(19) United States
(12) Patent Application Publication
(10) Pub. No.: US 2025/0054851 A1
(43) Pub. Date: Feb. 13, 2025

(54) Multi-mode Sensor Based on Wafer-level Packaging and its Manufacturing Method

(71) Applicant: Tsinghua University, Beijing (CN)

(72) Inventors: Chen Wang, Beijing (CN); Simian Zhang, Beijing (CN); Xiaonan Deng, Beijing (CN); Shengxian Ke, Beijing (CN); Yifei Wu, Beijing (CN); Zhengcao Li, Beijing (CN)

(73) Assignee: Tsinghua University, Beijing (CN)

(21) Appl. No.: 18/930,233

(22) Filed: Oct. 29, 2024

Related U.S. Application Data
(63) Continuation of application No. PCT/CN2023/091674, filed on Apr. 28, 2023.

(30) Foreign Application Priority Data
Apr. 29, 2022 (CN) 202210473821.1
Apr. 29, 2022 (CN) 202210475588.0

(51) Int. Cl. H01L 23/498; H01L 23/00; H01L 23/31

(52) U.S. Cl. CPC H01L 23/49827; H01L 23/3128; H01L 23/3142; H01L 23/315; H01L 23/564

(57) ABSTRACT

The present disclosure relates to a multi-mode sensor based on wafer-level packaging and its manufacturing method. The sensor comprises a base for 3D packaging, a multi-mode sensor body, a cap layer, and multiple packaging structures. The base consists of a first substrate, a dielectric layer, a first insulating layer, and multiple through silicon vias (TSVs). The cap layer comprises a second substrate and a bonding ring, where the first surface of the second substrate is provided with a cavity for housing at least part of the multi-mode sensor body. This disclosure has the advantages of high integration, high performance, low cost, miniaturization, high reliability, process feasibility and compatibility, as well as high wafer-level uniformity, making it suitable for a wide range of applications.

### CROSS-REFERENCE TO RELATED APPLICATIONS

This application is a continuation of International Application PCT/CN2023/091674, filed Apr. 28, 2023, which claims priority to China Patent Application No. 202210473821.1, filed Apr. 29, 2022, and China Patent Application No. 202210475588.0, filed Apr. 29, 2022. The above-referenced priority documents are incorporated herein by reference.

### TECHNICAL FIELD

This disclosure relates to the field of integrated circuit packaging and sensor technology, particularly to a multi-mode sensor based on wafer-level packaging and its manufacturing method.

### BACKGROUND

With the advancement of manufacturing technologies, advanced packaging techniques are gradually being applied in the sensor field. Compared to traditional sensors, multi-mode sensors with advanced packaging are smaller, lighter, consume less power, and are more cost-effective, making them more suitable for integration into smart devices and wearable electronics. As the demand for increased sensing parameters and multi-dimensional sensing grows, many multifunctional sensors are implemented through simple combinations of independent sensors, which presents numerous challenges in terms of efficiency, reliability, lightweight design, integration density, and cost.

While promoting the miniaturization of sensors, the design of multi-mode sensor chips in related technologies faces challenges. For example, device miniaturization and multi-mode requirements demand higher reliability, greater integration density, smaller sizes, and simplified packaging integration techniques. Additionally, the thin-film coating processes used need to be better compatible with wafer-level fabrication processes. More efficient wafer processing requires the design of wafer-level bonding, wafer-level bumping processes, and wafer-level packaging techniques. Moreover, the trend toward miniaturization and multi-mode capabilities imposes higher requirements for the controlled and uniform mass production of miniature multi-mode sensors. Furthermore, manufacturing multiple functional sensors on a single wafer may lead to issues such as exceeding thermal budgets, uncontrolled stress management, increased process complexity, skyrocketing process costs, and crosstalk between devices.

Therefore, how to provide a film-type multi-mode sensor and its manufacturing method that addresses the above issues is an urgent problem to be solved.

### BRIEF DESCRIPTION OF THE DRAWINGS

The accompanying drawings, which are comprised in and form part of the specification, illustrate exemplary embodiments, features, and aspects of the present disclosure and are used to explain the principles of the disclosure.

FIG. 1A illustrates a schematic structural diagram of a multi-mode sensor based on wafer-level packaging according to one embodiment of the present disclosure.

FIG. 1B illustrates a cross-sectional schematic diagram of a multi-mode sensor based on wafer-level packaging according to one embodiment of the present disclosure.

FIG. 2A illustrates a schematic structural diagram of a multi-mode sensor based on wafer-level packaging according to one embodiment of the present disclosure.

FIG. 2B illustrates a cross-sectional schematic diagram of a multi-mode sensor based on wafer-level packaging according to one embodiment of the present disclosure.

FIG. 3 illustrates a schematic structural diagram of a multi-mode sensor based on wafer-level packaging according to one embodiment of the present disclosure.

FIG. 4 illustrates a schematic structural diagram of a multi-mode sensor based on wafer-level packaging according to one embodiment of the present disclosure.

FIG. 5 illustrates a schematic structural diagram of a multi-mode sensor based on wafer-level packaging according to one embodiment of the present disclosure.

FIG. 6 illustrates a schematic structural diagram of the regulating electrodes according to one embodiment of the present disclosure.

FIG. 7 illustrates a schematic structural diagram of the sensing electrodes according to one embodiment of the present disclosure.

FIG. 8 illustrates a schematic structural diagram of the sensing film layer according to one embodiment of the present disclosure.

FIG. 9 illustrates a schematic diagram showing the relative positions of the heating electrodes, testing electrodes, and sensitive material layer according to one embodiment of the present disclosure.

FIG. 10A illustrates a top view of the cap layer according to one embodiment of the present disclosure.

FIG. 10B illustrates a top view of the cap layer of the multi-mode sensor based on wafer-level packaging according to one embodiment of the present disclosure.

FIG. 11 illustrates a schematic structural diagram of a multi-mode sensor based on wafer-level packaging according to one embodiment of the present disclosure.

FIG. 12 illustrates a flowchart of the manufacturing method for a multi-mode sensor based on wafer-level packaging according to one embodiment of the present disclosure.

FIG. 13 illustrates a schematic diagram of the manufacturing process for a multi-mode sensor based on wafer-level packaging according to one embodiment of the present disclosure.

FIG. 14 illustrates a schematic diagram of the manufacturing process for the multi-mode sensor body in the manufacturing method for a multi-mode sensor based on wafer-level packaging according to one embodiment of the present disclosure.

FIG. 15 illustrates a schematic diagram of the manufacturing process for the cap layer in the manufacturing method for a multi-mode sensor based on wafer-level packaging according to one embodiment of the present disclosure.

FIG. 16 illustrates a schematic diagram of the manufacturing process for a multi-mode sensor based on wafer-level packaging according to one embodiment of the present disclosure.

FIG. 17 illustrates a schematic diagram of the manufacturing process for the cap layer in the manufacturing method for a multi-mode sensor based on wafer-level packaging according to one embodiment of the present disclosure.

FIGS. 18A-18C illustrate schematic structural diagrams of a multi-mode sensor module based on wafer-level packaging according to one embodiment of the present disclosure.

FIG. 19 illustrates a schematic diagram of the secondary packaging structure of a multi-mode sensor assembly based on wafer-level packaging according to one embodiment of the present disclosure.

FIG. 20 illustrates a schematic diagram of the structure of a multi-mode sensor array based on wafer-level packaging according to one embodiment of the present disclosure.

FIGS. 21 and 22 illustrate schematic diagrams of the multi-packaging structure of a multi-mode sensor assembly based on wafer-level packaging according to another embodiment of the present disclosure.

FIG. 23 illustrates a schematic diagram of the secondary packaging manufacturing process for a multi-mode sensor array based on wafer-level packaging according to one embodiment of the present disclosure.

FIG. 24 illustrates a schematic diagram of the multi-packaging structure manufacturing process for a multi-mode sensor assembly based on wafer-level packaging according to one embodiment of the present disclosure.

FIG. 25 illustrates a characterization curve of wafer surface warpage during the base preparation process using a silicon dioxide insulating layer and metal electroplating process according to one embodiment of the present disclosure.

FIG. 26 illustrates a characterization curve of wafer surface warpage after using a silicon dioxide/silicon nitride composite film as an insulating layer according to one embodiment of the present disclosure.

FIG. 27 illustrates a characterization curve of wafer surface warpage after filling vias using a low-stress slow electroplating process according to one embodiment of the present disclosure.

### DETAILED DESCRIPTION

In view of the above, the present disclosure proposes a multi-mode sensor based on wafer-level packaging and its manufacturing method. The multi-mode sensor and its manufacturing method, as proposed in this disclosure, can measure various physical, chemical, and biological parameters, depending on different designs of the electrode circuit, sensing material preparation methods, and packaging methods. These parameters comprise mechanical vibration, speed, acceleration, flow rate, angular velocity, gap size, pressure, light intensity, images, temperature, humidity, gas types, concentration, aerosols, mRNA, DNA, and more.

In one aspect, embodiments of the present disclosure provide a multi-mode sensor based on wafer-level packaging. The multi-mode sensor comprises a base, a multi-mode sensor body, a cap layer, and multiple electrodes.

The base comprises: a first substrate, a dielectric layer, a first insulating layer, and multiple through silicon vias (TSVs). The dielectric layer covers at least a portion of the first surface of the first substrate; each of the TSVs penetrates the first substrate and the dielectric layer; the first insulating layer covers the second surface of the first substrate and at least exposes the through-via areas corresponding to the TSVs. The first substrate is a silicon substrate.

The electrodes are arranged in the through-via areas and are electrically connected to the corresponding TSVs.

The multi-mode sensor body comprises sensing electrodes and a sensing film layer, where the sensing electrodes are located above the dielectric layer and connected to the corresponding TSVs. The sensing film layer covers the target area of the sensing electrodes.

The cap layer comprises a second substrate and a bonding ring, wherein the first surface of the second substrate is provided with a cavity, and at least part of the multi-mode sensor body is positioned within the cavity. The bonding ring is arranged on the first surface of the second substrate and surrounds the cavity in a closed loop, used to fix the base and the cap layer together.

In one possible implementation, the multi-mode sensor body further comprises: regulating electrodes and a second insulating layer;

The regulating electrodes are located above the dielectric layer and connected to the corresponding TSVs;

The second insulating layer is located above the dielectric layer and at least covers the regulating electrodes, and the second insulating layer is provided with electrode vias to expose the TSVs connected to the sensing electrodes;

The sensing electrodes are located above the second insulating layer, and the target area overlaps the regulating electrodes, with the sensing electrodes connected to the corresponding TSVs through the electrode vias.

In one possible implementation, the dielectric layer covers the area of the first surface of the first substrate corresponding to the cavity, and the bonding ring is fixedly connected to the first surface of the first substrate, thereby fixing the base and the cap layer together, with the multi-mode sensor body and the dielectric layer located within the cavity; or

The dielectric layer covers the entire area of the first surface of the first substrate, and the bonding ring is fixedly connected to the dielectric layer, thereby fixing the base and the cap layer together, with at least the sensing film layer of the multi-mode sensor body located within the cavity.

In one possible implementation, the dielectric layer covers the area of the first surface of the first substrate corresponding to the cavity, and the second insulating layer covers at most the exposed part of the dielectric layer. The bonding ring is fixedly connected to the first surface of the first substrate, thereby fixing the base and the cap layer together, with the multi-mode sensor body and the dielectric layer located within the cavity; or

The dielectric layer covers the entire area of the first surface of the first substrate, and the second insulating layer covers at most the exposed part of the dielectric layer corresponding to the cavity. The bonding ring is fixedly connected to the dielectric layer, thereby fixing the base and the cap layer together, with the multi-mode sensor body located within the cavity; or

The dielectric layer covers the entire area of the first surface of the first substrate, and the second insulating layer also covers the entire exposed part of the dielectric layer. The bonding ring is fixedly connected to the second insulating layer, thereby fixing the base and the cap layer together, with at least the sensing film layer located within the cavity.

In one possible implementation, the shape of the regulating electrodes comprises an extendable shape, wherein the extendable shape is any one of a serpentine shape or an S-shape;

The sensing electrodes comprise interdigitated electrodes and/or intersecting electrodes, and the target area is a periodic pattern area of the sensing electrodes, where the size of the extendable shape area of the regulating electrodes matches and overlaps the target area.

In one possible implementation, the multi-mode sensor body further comprises a sensing structure, wherein the sensing structure is located above or inside the base, and the sensing structure comprises at least one of the following: multiple composite film layers or a geometric structure with a preset 3D shape.

In one possible implementation, the multi-mode sensor body is used for detecting external gases, and the second surface of the second substrate is further provided with a material exchange via that corresponds to and connects with the cavity, positioned in alignment with the target area.

In one possible implementation, the cap layer further comprises:

A breathable membrane layer, located above the second surface of the second substrate, covering at least the material exchange via.

In one possible implementation, the cap layer further comprises:

A dustproof mesh layer, located on the second surface of the second substrate, covering at least the area of the breathable membrane layer that corresponds to the material exchange via, wherein the part of the dustproof mesh layer corresponding to the material exchange via is provided with multiple through-vias.

In a second aspect, a manufacturing method for a multi-mode sensor based on wafer-level packaging is provided. The method comprises: a base manufacturing step, a multi-mode sensor body manufacturing step, a cap layer manufacturing step, a fixed connection step, and an electrode manufacturing step.

The base manufacturing step comprises: preparing a dielectric layer on the first surface of the first substrate; etching the first substrate and the dielectric layer, and thinning the first substrate to form multiple TSVs; preparing a first insulating layer on the second surface of the first substrate, and etching the first insulating layer to at least expose the through-via areas corresponding to the TSVs, thereby obtaining the base of the multi-mode sensor.

The multi-mode sensor body manufacturing step comprises: manufacturing sensing electrodes above the dielectric layer; manufacturing a sensing film layer above the target area of the sensing electrodes, thereby obtaining the multi-mode sensor body.

The cap layer manufacturing step comprises: preparing a bonding ring on the first surface of the second substrate; etching the first surface of the second substrate to form a cavity, thereby obtaining the cap layer of the multi-mode sensor.

The fixed connection step comprises: bonding the bonding ring with the base so that at least part of the multi-mode sensor body is positioned within the cavity.

The electrode manufacturing step comprises: bumping in each of the through-via areas to form the electrodes of the multi-mode sensor, completing the preparation of the multi-mode sensor.

In one possible implementation, sensing electrodes are manufactured above the dielectric layer; a sensing film layer is manufactured above the target area of the sensing electrodes, thereby obtaining the multi-mode sensor body, which comprises:

Sequentially manufacturing regulating electrodes and a second insulating layer above the dielectric layer, wherein the second insulating layer at least covers the regulating electrodes;

Etching the second insulating layer to form electrode vias, exposing the TSVs for connection with the sensing electrodes;

Manufacturing sensing electrodes on the second insulating layer, wherein the target area overlaps the regulating electrodes, and the sensing electrodes are connected to the corresponding TSVs through the electrode vias;

Manufacturing a sensing film layer above the target area, thereby obtaining the multi-mode sensor body.

In one possible implementation, the bonding ring is fixedly connected to the base by a bonding method, including any one of the following steps:

If the dielectric layer covers the area of the first surface of the first substrate corresponding to the cavity, the bonding ring is fixedly connected to the first surface of the first substrate by a bonding method, thereby fixing the base and the cap layer together, with the multi-mode sensor body and the dielectric layer located within the cavity; or

If the dielectric layer covers the entire area of the first surface of the first substrate, the bonding ring is fixedly connected to the dielectric layer by a bonding method, thereby fixing the base and the cap layer together, with at least the sensing film layer of the multi-mode sensor body located within the cavity.

In one possible implementation, the bonding ring is fixedly connected to the base by a bonding method, including any one of the following steps:

If the dielectric layer covers the area of the first surface of the first substrate corresponding to the cavity, and the second insulating layer covers at most the exposed part of the dielectric layer, the bonding ring is fixedly connected to the first surface of the first substrate by a bonding method, thereby fixing the base and the cap layer together, with the multi-mode sensor body and the dielectric layer located within the cavity;

If the dielectric layer covers the entire area of the first surface of the first substrate, and the second insulating layer covers at most the exposed part of the dielectric layer corresponding to the cavity, the bonding ring is fixedly connected to the dielectric layer by a bonding method, thereby fixing the base and the cap layer together, with the multi-mode sensor body located within the cavity;

If the dielectric layer covers the entire area of the first surface of the first substrate, and the second insulating layer also covers the entire exposed part of the dielectric layer, the bonding ring is fixedly connected to the second insulating layer by a bonding method, thereby fixing the base and the cap layer together, with at least the sensing film layer located within the cavity.

In one possible implementation, the shape of the regulating electrodes comprises an extendable shape, wherein the extendable shape is any one of a serpentine shape or an S-shape; and/or

The sensing electrodes comprise interdigitated electrodes and/or intersecting electrodes, and the target area is a periodic pattern area of the interdigitated or intersecting electrodes, where the size of the extendable shape area of the regulating electrodes matches and overlaps the target area.

In one possible implementation, the multi-mode sensor body further comprises a sensing structure, wherein the sensing structure is located above or inside the base, and the sensing structure comprises at least one of the following: multiple composite film layers or a geometric structure with a preset 3D shape.

In one possible implementation, the cap layer manufacturing step further comprises:

Etching the second substrate to form a material exchange via that penetrates the second substrate and corresponds to the target area before etching the first surface of the second substrate to form a cavity, wherein the cavity is connected to the through-via.

In one possible implementation, the cap layer manufacturing step further comprises:

Attaching a pre-prepared breathable membrane to the second surface of the second substrate, covering at least the material exchange via, thereby forming a breathable membrane layer.

In one possible implementation, the cap layer manufacturing step further comprises:

Preparing a dustproof mesh layer above the breathable membrane layer, wherein the dustproof mesh layer is provided with multiple through-vias and covers at least a portion of the breathable membrane layer.

Through the multi-mode sensor and its manufacturing method provided in the above first and second aspects, the system can be optimized through an integrated design, offering high performance, low cost, miniaturization, high reliability, high process feasibility and compatibility, and high wafer-level uniformity. By setting the manufacturing process based on dynamic stress regulation and compensation for the entire wafer, high process compatibility, and thermal budget management and distribution, the method avoids yield loss caused by excessive stress, poor process compatibility, or thermal failure during manufacturing. It can be widely applied in the production and packaging of wafer-level multi-mode sensors, such as gas multi-mode sensors, pressure multi-mode sensors, and temperature multi-mode sensors.

In a third aspect, embodiments of the present disclosure provide a multi-mode sensor based on wafer-level packaging. The multi-mode sensor comprises: a base, a multi-mode sensor body for detecting a target in the external environment, a cap layer, and multiple electrodes.

The base comprises: a first substrate, a dielectric layer, a first insulating layer, and multiple TSVs. The dielectric layer covers at least a portion of the first surface of the first substrate; each of the TSVs penetrates the first substrate and the dielectric layer; the first insulating layer covers the second surface of the first substrate and at least exposes the through-via areas corresponding to the TSVs. The first substrate is a silicon substrate.

The electrodes are arranged in the corresponding through-via areas and are electrically connected to the corresponding TSVs.

The multi-mode sensor body comprises regulating electrodes, a second insulating layer, sensing electrodes, and a sensing film layer. The regulating electrodes are located above the dielectric layer and connected to the corresponding TSVs; the second insulating layer is located above the dielectric layer and at least covers the regulating electrodes; the sensing electrodes are located above the second insulating layer, with the target area overlapping the regulating electrodes, and are connected to the corresponding TSVs through the vias in the second insulating layer; the sensing film layer is located above the second insulating layer and covers the target area of the sensing electrodes.

The cap layer comprises a second substrate and a bonding ring. The first surface of the second substrate is provided with a cavity, and at least part of the multi-mode sensor body is positioned within the cavity. The second surface of the second substrate is provided with a material exchange via that corresponds to and connects with the cavity, positioned in alignment with the target area. The bonding ring is arranged on the first surface of the second substrate, surrounding the cavity in a closed loop, and is used to fix the base and the cap layer together.

In one possible implementation, the cap layer further comprises:

A breathable membrane layer, located above the second surface of the second substrate, covering at least the material exchange via.

In one possible implementation, the cap layer further comprises:

A dustproof mesh layer, located on the second surface of the second substrate, covering at least the area of the breathable membrane layer that corresponds to the material exchange via, wherein the part of the dustproof mesh layer corresponding to the material exchange via is provided with multiple through-vias.

In one possible implementation, the dielectric layer covers the area of the first surface of the first substrate corresponding to the cavity, and the second insulating layer covers at most the exposed part of the dielectric layer. The bonding ring is fixedly connected to the first surface of the first substrate, thereby fixing the base and the cap layer together, with the multi-mode sensor body and the dielectric layer located within the cavity; or

The dielectric layer covers the entire area of the first surface of the first substrate, and the second insulating layer covers at most the exposed part of the dielectric layer corresponding to the cavity. The bonding ring is fixedly connected to the dielectric layer, thereby fixing the base and the cap layer together, with the multi-mode sensor body located within the cavity; or

The dielectric layer covers the entire area of the first surface of the first substrate, and the second insulating layer also covers the entire exposed part of the dielectric layer. The bonding ring is fixedly connected to the second insulating layer, thereby fixing the base and the cap layer together, with at least the sensing film layer of the multi-mode sensor body located within the cavity.

In one possible implementation, the shape of the regulating electrodes comprises an extendable shape, wherein the extendable shape is any one of a serpentine shape or an S-shape; and/or

The sensing electrodes comprise interdigitated electrodes and/or intersecting electrodes, and the target area is a periodic pattern area of the sensing electrodes. The size of the extendable shape area of the regulating electrodes matches and overlaps the target area.

In one possible implementation, the multi-mode sensor body further comprises a sensing structure, wherein the sensing structure is located above or inside the base, and the sensing structure comprises at least one of the following: multiple composite film layers or a geometric structure with a preset 3D shape.

In a fourth aspect, a manufacturing method for a multi-mode sensor based on wafer-level packaging is provided for manufacturing the above-mentioned multi-mode sensor. The method comprises: a base manufacturing step, a multi-mode sensor body manufacturing step, a cap layer manufacturing step, a fixed connection step, and an electrode manufacturing step.

The base manufacturing step comprises: preparing a dielectric layer on the first surface of the first substrate; etching the first substrate and the dielectric layer, and thinning the first substrate to form multiple TSVs; preparing a first insulating layer on the second surface of the first substrate, and etching the first insulating layer to at least expose the through-via areas corresponding to the TSVs, thereby obtaining the base of the multi-mode sensor.

The multi-mode sensor body manufacturing step comprises: sequentially manufacturing regulating electrodes and a second insulating layer above the dielectric layer, wherein the second insulating layer at least covers the regulating electrodes; etching the second insulating layer to expose the TSVs for connection with the sensing electrodes; manufacturing sensing electrodes on the second insulating layer, where the target area overlaps the regulating electrodes, and connecting the sensing electrodes to the exposed TSVs through the second insulating layer; manufacturing a sensing film layer above the target area, thereby obtaining the multi-mode sensor body.

The cap layer manufacturing step comprises: preparing a bonding ring on the first surface of the second substrate; etching the second substrate to form a material exchange via that penetrates the second substrate and corresponds to the target area; etching the first surface of the second substrate to form a cavity connected to the material exchange via, thereby obtaining the cap layer of the multi-mode sensor.

Fixed connection step: Bonding the bonding ring with the base so that at least part of the multi-mode sensor body is positioned within the cavity.

Electrode manufacturing step: Bumping in each of the through-via areas to form the electrodes of the multi-mode sensor, completing the preparation of the multi-mode sensor.

In one possible implementation, the cap layer manufacturing step further comprises:

Attaching a pre-prepared breathable membrane to the second surface of the second substrate, covering at least the material exchange via, thereby forming a breathable membrane layer.

In one possible implementation, the cap layer manufacturing step further comprises:

Preparing a dustproof mesh layer above the breathable membrane layer, wherein the dustproof mesh layer is provided with multiple through-vias and covers at least a portion of the breathable membrane layer.

In one possible implementation, the bonding ring is fixedly connected to the base by a bonding method, including any one of the following steps:

If the dielectric layer covers the area of the first surface of the first substrate corresponding to the cavity, and the second insulating layer covers at most the exposed part of the dielectric layer, the bonding ring is fixedly connected to the first surface of the first substrate by a bonding method, thereby fixing the base and the cap layer together, with the multi-mode sensor body and the dielectric layer located within the cavity;

If the dielectric layer covers the entire area of the first surface of the first substrate, and the second insulating layer covers at most the exposed part of the dielectric layer corresponding to the cavity, the bonding ring is fixedly connected to the dielectric layer by a bonding method, thereby fixing the base and the cap layer together, with the multi-mode sensor body located within the cavity;

If the dielectric layer covers the entire area of the first surface of the first substrate, and the second insulating layer also covers the entire exposed part of the dielectric layer, the bonding ring is fixedly connected to the second insulating layer by a bonding method, thereby fixing the base and the cap layer together, with at least the sensing film layer of the multi-mode sensor body located within the cavity.

In one possible implementation, the shape of the regulating electrodes comprises an extendable shape, wherein the extendable shape is any one of a serpentine shape or an S-shape; and/or

The sensing electrodes comprise interdigitated electrodes or intersecting electrodes, and the target area is a periodic pattern area of the interdigitated or intersecting electrodes. The size of the extendable shape area of the regulating electrodes matches and overlaps the target area; and/or

The sensing film layer is a self-assembled cluster of spherical gas-sensitive materials.

Through the multi-mode sensor based on wafer-level packaging and its manufacturing method provided in the above third and fourth aspects, the sensing film area is separated from the interconnection line area, and the core structure of the multi-mode sensor body is protected, enhancing the sensor's impact resistance and anti-pollution capabilities. This reduces manufacturing costs, improves compatibility with wafer-level manufacturing processes, and enhances the uniformity of packaging quality and precision through wafer-level packaging technology, thereby improving industrial production efficiency.

In a fifth aspect, embodiments of the present disclosure provide a multi-mode sensor module based on wafer-level packaging, comprising: multiple multi-mode sensors based on wafer-level packaging as described above, vertically stacked in succession.

In a sixth aspect, embodiments of the present disclosure provide a multi-mode sensor assembly based on wafer-level packaging, comprising: a top secondary packaging layer, multiple sensor layers, a secondary packaging via interconnection layer, and a bottom secondary packaging layer, wherein each of the sensor layers is provided with multiple multi-mode sensors based on wafer-level packaging as described above.

In a seventh aspect, embodiments of the present disclosure provide a multi-mode sensor assembly based on wafer-level packaging, comprising: a top secondary packaging layer, the multi-mode sensor module based on wafer-level packaging as described in the fifth aspect, a secondary packaging via interconnection layer, and a bottom secondary packaging layer.

In an eighth aspect, embodiments of the present disclosure provide a multi-mode sensor assembly based on wafer-level packaging, comprising: multiple sensor layers and at least two base sidewalls, wherein each of the sensor layers is provided with multiple multi-mode sensors based on wafer-level packaging as described above;

Each of the sensor layers is fixedly bonded and connected to the corresponding base sidewalls, and each of the multi-mode sensors is laterally connected to the respective base sidewalls through the TSVs and interconnection lines within their respective bases, achieving electrical connection with the surface lines of the base sidewalls.

In a ninth aspect, embodiments of the present disclosure provide a multi-mode sensor array based on wafer-level packaging, comprising: a top secondary packaging cap wafer, a multi-layer sensor layer wafer, a secondary packaging via interconnection wafer, and a bottom secondary packaging layer wafer, wherein each sensor layer wafer comprises multiple multi-mode sensors based on wafer-level packaging as described above.

The integrated multi-mode sensors are directly interconnected through the back of the wafer, and during the subsequent processing, multiple interconnected sensing units are uniformly diced and packaged, avoiding the inefficiency of integrating each individual sensing microsystem chip with processing circuits. Additionally, after wafer-level production, packaging and testing can be completed on the wafer surface, particularly for testing interconnected circuits. This improves the production efficiency of multi-mode sensing microsystem chips, shortens the design and production cycle, and reduces overall costs.

The other features and aspects of this disclosure will become clear from the detailed description of exemplary embodiments provided below with reference to the accompanying drawings.

### DETAILED DESCRIPTION OF EMBODIMENTS

The various exemplary embodiments, features, and aspects of the present disclosure will be described in detail below with reference to the accompanying drawings. In the drawings, the same reference numerals represent elements with the same or similar functions. Although various aspects of the embodiments are illustrated in the drawings, the figures are not necessarily drawn to scale unless specifically noted.

The term “exemplary” as used here means “serving as an example, instance, or illustration.” Any embodiment described as “exemplary” should not be interpreted as being superior to or better than other embodiments.

Additionally, to better explain the present disclosure, numerous specific details are provided in the following detailed description. However, it should be understood by those skilled in the art that the present disclosure can still be practiced without certain specific details. In some instances, methods, techniques, elements, and circuits well known to those skilled in the art are not described in detail in order to highlight the essence of the present disclosure.

To address the above technical issues, embodiments of the present disclosure provide a multi-mode sensor based on wafer-level packaging and its manufacturing method. The multi-mode sensor produced through this method can be optimized for system-level design, offering high performance, low cost, miniaturization, high reliability, high process feasibility and compatibility, and high wafer-level uniformity. The manufacturing and packaging process for the multi-mode sensor based on wafer-level bonding can be configured according to dynamic stress regulation and compensation for the entire wafer, high process compatibility, and thermal budget management and distribution, thereby avoiding yield loss caused by excessive stress, poor process compatibility, or thermal failure during manufacturing. This method can be widely applied to the preparation and packaging of wafer-level multi-mode sensors, such as gas multi-mode sensors, pressure multi-mode sensors, and temperature multi-mode sensors.

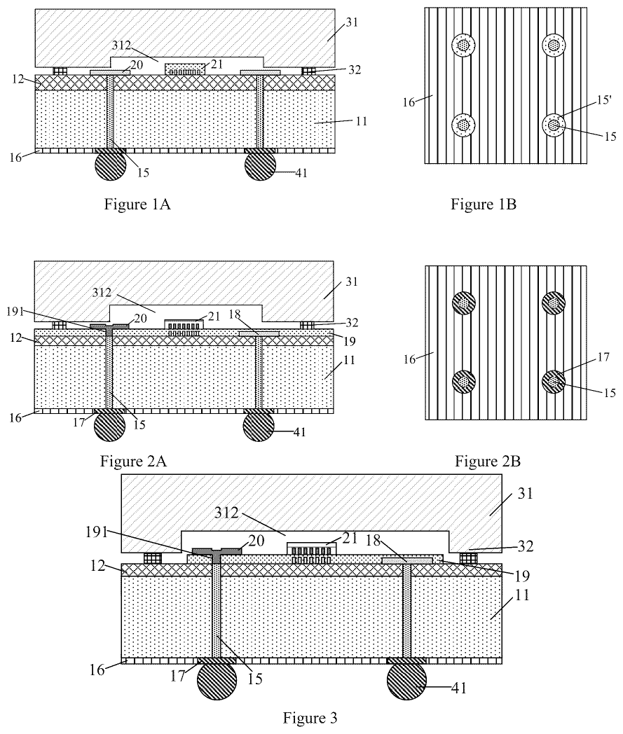

FIGS. 1A, 2A, and 3-5 illustrate schematic structural diagrams of a multi-mode sensor based on wafer-level packaging according to one embodiment of the present disclosure. The present disclosure also provides a multi-mode sensor module, which comprises one or more multi-mode sensors of the present disclosure. The types and number of multi-mode sensors in the multi-mode sensor module can be configured according to actual needs, and the present disclosure does not impose any limitations in this regard.

As shown in FIG. 1A, the multi-mode sensor comprises a base, a multi-mode sensor body, a cap layer, and multiple electrodes 41. The base may comprise a first substrate 11, a dielectric layer 12, a first insulating layer 16, and multiple TSVs 15. The multi-mode sensor body comprises sensing electrodes 20 and a sensing film layer 21. The cap layer comprises a second substrate 31 and a bonding ring 32.

As shown in FIG. 1A, the base may comprise a first substrate 11, a dielectric layer 12, a first insulating layer 16, and multiple TSVs 15. The dielectric layer 12 covers at least a portion of the first surface of the first substrate 11. Each TSV 15 penetrates through the first substrate 11 and the dielectric layer 12. The first insulating layer 16 covers the second surface of the first substrate 11 and at least exposes the through-via areas corresponding to the TSVs 15 (as shown in FIG. 1B). The first substrate 11 is a silicon substrate. FIGS. 1B and 2B are only illustrative examples provided by this disclosure, and those skilled in the art can configure the position and number of TSVs according to actual needs, without any limitation imposed by this disclosure.

In this embodiment, the dielectric layer is used to isolate the first substrate from the sensing electrodes in the multi-mode sensor body, as well as from the regulating electrodes described below. The dielectric layer can be an ONO dielectric layer, where the ONO dielectric layer is composed of silicon dioxide (SiO₂)/silicon nitride (SiNx)/silicon dioxide layers, which can be prepared using processes such as Plasma Enhanced Chemical Vapor Deposition (PECVD). Since silicon nitride and silicon dioxide have opposite thermal expansion characteristics, the ONO dielectric layer can reduce additional stress caused by thermal expansion during high-temperature processes.

For example, as shown in FIG. 5, the dielectric layer 12 may comprise a silicon dioxide layer 121, a silicon nitride layer 122, and a silicon dioxide layer 123. The diameter of the TSVs 15 can range from 1 μm to 50 μm, with an aspect ratio of 5:1 to 10:1. The first insulating layer can be made of silicon dioxide or other insulating materials, and its thickness can range from 300 nm to 1000 nm. Those skilled in the art can configure the materials and dimensions of the dielectric layer, the first insulating layer, and the TSVs according to actual needs, without any limitation imposed by this disclosure.

As shown in FIG. 1A, each electrode 41 is arranged in the corresponding through-via area 15′ and electrically connected to the corresponding TSV 15. In this way, by connecting the electrode 41 below the TSV 15, planar metal wiring is reduced, and the testing area is effectively isolated from the electrical area, thereby improving device reliability and achieving miniaturization of the device.

In this embodiment, the electrodes 41 can be metal balls manufactured by bumping methods such as laser bumping. The material of the metal balls can be lead-tin alloy (PbSn) or other suitable materials. As shown in FIGS. 2A, 2B, and FIGS. 3 to 5, the multi-mode sensor may further comprise a metal electrode deposition layer 17. The metal electrode deposition layer 17 is located in the through-via areas 15′ and covers the through-via areas 15′. The material of the metal electrode deposition layer 17 can be titanium (Ti), platinum (Pt), gold (Au), or other metals. The thickness of the metal electrode deposition layer 17 can be 550 nm. The metal electrode deposition layer 17 facilitates the subsequent preparation of the electrodes 41 through the bumping process, ensuring the smooth progress of bumping. Those skilled in the art can configure the materials and dimensions of the metal electrode deposition layer and the electrodes according to actual needs, without any limitation imposed by this disclosure.

As shown in FIG. 1A, the multi-mode sensor body comprises sensing electrodes 20 and a sensing film layer 21. The sensing electrodes 20 are located above the dielectric layer 12 and connected to the corresponding TSVs 15. The sensing film layer 21 covers the target area of the sensing electrodes 20 or is located beneath the target area.

In this embodiment, the material of the sensing film layer can be the oxide, metal, polymer, or other materials, which can be switched according to actual needs. The sensing film layer can be formed by self-assembly or wafer-level coating and patterned through photolithography to ensure better compatibility with wafer-level manufacturing technology. During the operation of the multi-mode sensor body, a certain voltage can be applied across the sensing electrodes. When the sensing film layer undergoes specific changes during the sensing process, the electrical signal across the sensing electrodes changes, and the corresponding detection can be achieved by reading this signal change.

In one possible implementation, as shown in FIGS. 2A and 3-5, if the sensing film layer 21 in the manufactured multi-mode sensor requires external regulation for normal operation, the multi-mode sensor body may further comprise regulating electrodes 18 and a second insulating layer 19. The regulating electrodes 18 are located above the dielectric layer 12 and connected to the corresponding TSVs 15. The second insulating layer 19 is located above the dielectric layer 12 and at least covers the regulating electrodes 18. The second insulating layer 19 is provided with electrode vias 191 to expose the TSVs 15 connected to the sensing electrodes 20.

If the multi-mode sensor body further comprises regulating electrodes 18 and a second insulating layer 19, the sensing electrodes 20 are located above the second insulating layer 19, and the target area overlaps with the regulating electrodes 18, connecting to the corresponding TSVs 15 through the electrode vias 191.

In this implementation, the regulating electrodes 18 are used to generate changes in temperature, mechanical strain, magnetic field, polarization, or light emission when powered. These external condition changes can regulate the sensing film layer 21 in the multi-mode sensor body by adjusting the temperature, stress, or magnetic polarization intensity of the sensing film layer 21, ensuring that the sensing film layer 21 is in the required working state during the operation of the multi-mode sensor, thereby enabling the multi-mode sensor body to perform the corresponding detection. The regulating electrodes can be made of materials such as metallic resistance wires, electrostrictive materials, electromagnets, ferroelectric materials, or photovoltaic materials. Multiple regulating electrodes can be arranged, and their shape, size, arrangement order, and material can be designed as needed, without limitation imposed by the present invention.

Exemplarily, if the multi-mode sensor is a gas sensor or other types of sensors that need to detect external substances, the multi-mode sensor body may further comprise regulating electrodes 18 and a second insulating layer 19. If the multi-mode sensor is a gas sensor, the material of the sensing film layer 21 can be gas-sensitive material, and the regulating electrodes 18 can be heating electrodes. Once the gas-sensitive material is heated by the regulating electrodes 18 into its working state, it can specifically bind with gas molecules. The specific binding between the gas-sensitive material layer and gas molecules varies depending on the type and concentration of the gases in the environment, which causes differences in the resistance of the gas-sensitive material layer. During the monitoring process, a constant voltage is applied to the sensing electrodes 20, and the current flowing through the sensing electrodes 20 is measured. Since the resistance of the gas-sensitive material layer changes due to its specific binding with gas molecules, the current detected at the sensing electrodes 20 will also change. Based on the changes in current, the resistance change of the gas-sensitive material layer can be determined, and thus the type and concentration of the gas combined with the gas-sensitive material layer can be identified. The gas-sensitive material can be set according to the type and concentration of gas to be detected, with no limitation imposed by this disclosure.

The second insulating layer 19 is used to electrically isolate the sensing electrodes 20 from the regulating electrodes 18, ensuring that the sensing electrodes 20 and regulating electrodes 18 are not interconnected. The material of the second insulating layer 19 can be an insulating material such as silicon dioxide or silicon nitride, without limitation imposed by this disclosure.

In one possible implementation, if the multi-mode sensor is a gas sensor, the TSVs 15 connecting the regulating electrodes 18 and the sensing electrodes 20 can be symmetrically located at the four corners of the cavity 312 and inside the cavity 312. The depth of the cavity 312 (the distance between the top of the cavity 312 and the top of the multi-mode sensor body) should be more than 100 μm to provide a stable gas layer on the surface of the multi-mode sensor body, allowing the sensing film layer 21 to fully interact with gas molecules.

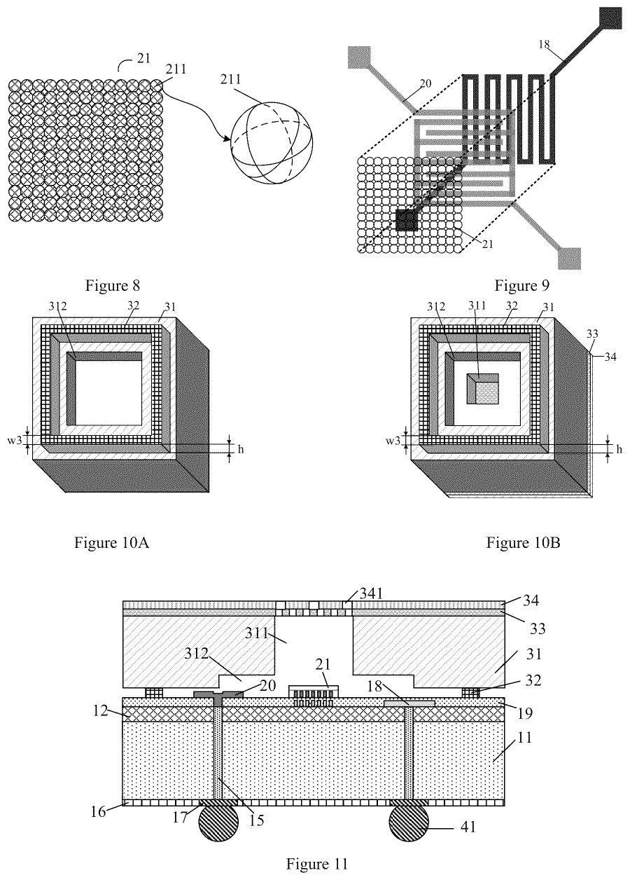

FIG. 6 illustrates a schematic diagram of the structure of the regulating electrodes according to one embodiment of the present disclosure. FIG. 7 illustrates a schematic diagram of the structure of the sensing electrodes according to one embodiment of the present disclosure. FIG. 8 illustrates a schematic diagram of the structure of the sensing film layer according to one embodiment of the present disclosure. FIG. 9 illustrates a schematic diagram of the relative positions of the regulating electrodes, sensing electrodes, and the sensing film layer according to one embodiment of the present disclosure. For clarity in illustrating the spatial relationship between the regulating electrodes 18, sensing electrodes 20, and the sensing film layer 21, the second insulating layer 19 is not shown in FIG. 9.

In one possible implementation, the shape of the regulating electrodes 18 can comprise extendable shapes, such as the serpentine or S-shaped configurations shown in FIGS. 6 and 9. This design can increase the length of the regulating electrodes. The regulating electrodes 18 can comprise an extendable shape area M1, a first connection zone 181 for connecting to the TSVs 15, and a first wiring zone 182 that connects the extendable shape area M1 to the first connection zone 181.

In one possible implementation, as shown in FIG. 7, the sensing electrodes 20 can be interdigitated electrodes, intersecting electrodes, or other types of electrodes. The interdigitated electrodes can be connected through the sensing film layer 21, which covers them. The sensing electrodes 20 can comprise a periodic pattern area M2, a second connection zone 201 for connecting to the TSVs 15, and a second wiring zone 202 that connects the periodic pattern area M2 to the second connection zone 201. The target area can be the periodic pattern area M2.

In this design, the width w1 of the extendable shape area M1 and the first wiring zone 182 of the regulating electrodes 18 is equal to the width w2 of the interdigitated electrodes (i.e., the width of the periodic pattern area M2 and the second connection zone 201), meaning w1=w2. The distance s1 between the metal strips in the extendable shape area M1 is the same as the distance between the metal strips in the interdigitated electrodes (i.e., the distance between the metal strips in the periodic pattern area M2), meaning s1=s2. Additionally, w1 and s1 can be equal. The size of the extendable shape area M1 is the same as that of the periodic pattern area M2. The number of periods in the extendable shape area M1 and the periodic pattern area M2 can also be the same. For example, as shown in FIGS. 6 and 9, the extendable shape area M1 has 4 periods, and as shown in FIGS. 7 and 9, the periodic pattern area M2 also has 4 periods. The thickness of the regulating electrodes 18 and the sensing electrodes 20 can be the same, and this thickness can range from 80 nm to 150 nm, for example, with the thickness of both the regulating electrodes 18 and the sensing electrodes 20 set at 110 nm.

In this implementation, the materials for the regulating electrodes 18 and the sensing electrodes 20 can be metals such as titanium (Ti), platinum (Pt), or other suitable materials, with no limitation imposed by this disclosure.

In one possible implementation, as shown in FIGS. 8 and 9, the sensing film layer 21 can be a self-assembled cluster of spherical sensitive material 211. The size of the sensing film layer 21 can be slightly smaller than or equal to the size of the periodic pattern area M2, ensuring that the sensing film layer 21 can fully cover the periodic pattern area M2, thus ensuring electrical continuity of the sensor circuit.

In this embodiment, the size of the sensing film layer 21, sensing electrodes 20, and regulating electrodes 18 can be configured based on the sensor's dimensions. Assuming that the size of the sensing film layer 21 is set between 100 μm×100 μm and 300 μm×300 μm based on the sensor size, then s1, s2, w1, and w2 can range from 5 μm to 20 μm, and the length of the sensing electrodes 20 and regulating electrodes 18 can range from 35 μm to 380 μm. It is understood that those skilled in the art can configure the size, materials, and other specifications of each part of the sensor body based on actual needs, and this disclosure does not impose any limitations in this regard.

FIG. 10A shows a top view of the cap layer according to one embodiment of the present disclosure. As shown in FIGS. 1A, 2A, 3-5, and 10A, the cap layer may comprise a second substrate 31 and a bonding ring 32. The first surface of the second substrate 31 is provided with a cavity 312, in which at least part of the multi-mode sensor body is located. The bonding ring 32 is arranged on the first surface of the second substrate 31, surrounding the cavity 312 in a closed loop, and is used to fix the base and the cap layer together.

FIG. 10B shows a top view of the cap layer of the multi-mode sensor based on wafer-level packaging according to one embodiment of the present disclosure. FIG. 11 illustrates a schematic structural diagram of the gas sensor based on wafer-level packaging according to one embodiment of the present disclosure. When the multi-mode sensor is a gas sensor, as shown in FIGS. 10B and 11, in one possible implementation, if the multi-mode sensor is a gas sensor, the cap layer may also comprise a breathable membrane layer 33, or the cap layer may comprise both a breathable membrane layer 33 and a dustproof mesh layer 34. The second surface of the second substrate 31 can be provided with a material exchange via 311, which connects to the cavity 312 and corresponds to the target area. The breathable membrane layer 33 is located above the second surface of the second substrate 31 and at least covers the material exchange via 311. The dustproof mesh layer 34 is located on the second surface of the second substrate 31, at least covering the area of the breathable membrane layer 33 corresponding to the material exchange via 311. The part of the dustproof mesh layer 34 corresponding to the material exchange via 311 is provided with multiple through-vias 341.

In this implementation, the breathable membrane layer 33 can either cover the entire area of the second surface of the second substrate 31 (as shown in FIG. 11) or only cover the area of the second surface of the second substrate 31 corresponding to the material exchange via 311. The breathable membrane layer 33 has selective permeability, allowing gas to enter the material exchange via 311 while blocking micron-level contaminants from entering the material exchange via 311. For example, the material of the breathable membrane layer 33 can be a polymer. This prevents contaminants from polluting and damaging the sensing film layer in the multi-mode sensor. Those skilled in the art can configure the material and thickness of the breathable membrane layer according to actual needs, and this disclosure does not impose any limitations in this regard.

The dustproof mesh layer 34 can cover the entire area of the breathable membrane layer 33 (as shown in FIG. 11) or only cover the area of the breathable membrane layer 33 corresponding to the material exchange via 311. The size of the dustproof mesh layer 34 may be the same as or different from that of the breathable membrane layer 33, without limitation imposed by this disclosure. The dustproof mesh layer 34 is used to block dust and other large particles from falling through the material exchange via 311 and entering the interior of the multi-mode sensor, thus preventing contamination and mechanical damage to the sensing film layer. The material of the dustproof mesh layer 34 can be metal or other materials resistant to corrosive gases, enhancing the reliability of the multi-mode sensor. For example, the material of the dustproof mesh layer 34 can be platinum (Pt). The thickness of the dustproof mesh layer 34 can range from 100 nm to 300 nm. Those skilled in the art can configure the material and thickness of the dustproof mesh layer based on actual needs, with no limitations imposed by this disclosure.

In one possible implementation, if the multi-mode sensor is a gas sensor, the cap layer can comprise only the dustproof mesh layer (i.e., without the breathable membrane layer). The dustproof mesh layer is located on the second surface of the second substrate 31, at least covering the area corresponding to the material exchange via 311. The part of the dustproof mesh layer covering at least the material exchange via 311 is provided with multiple through-vias 341.

In one possible implementation, the multi-mode sensor may also comprise a processing module. This processing module is used to control the powering of the regulating electrodes and sensing electrodes, so that during the operation of the multi-mode sensor, the regulating electrodes can be powered to adjust the sensing film layer to the required working state. During the operation of the multi-mode sensor, the processing module itself or in conjunction with the corresponding detection module monitors the current flowing through the sensing electrodes, and based on the monitoring results, determines relevant data regarding the detected object by the multi-mode sensor. The detected object can be any physical, chemical, or biological parameter, such as physical parameters (temperature, humidity, acceleration, vibration, image, etc.), chemical parameters (organic molecules, inorganic molecules, composite material branches, gas composition, liquid composition), or biological parameters (mRNA, DNA, viruses, bacteria, etc.), without limitation imposed by this disclosure. For example, if the detected object is a gas, the relevant data determined can be the type and/or concentration.

In this embodiment, the thickness of the cap layer can range from 200 μm to 400 μm. The first substrate and the second substrate can be made of silicon or other materials to ensure high compatibility with device layer manufacturing processes and to guarantee matching contact strength between the first substrate, base, and bonding ring. The material of the cap layer can also be glass or other materials, without limitation imposed by this disclosure.

In this embodiment, the cap layer and the base can have the same dimensions and similar or identical thickness and structure. This ensures that the base and cap layer have comparable mechanical properties, avoiding issues such as mismatched coefficients of expansion or compressive strength during bonding and subsequent operations. The material of the bonding ring 32 can be a material that bonds easily with the base. For example, the bonding ring 32 can be made of gold (Au), AuSn alloy, polymer materials, or other materials that provide sufficient bonding strength, without limitation imposed by this disclosure. To ensure the reliability of the fixed connection between the cap layer and the base, the width w3 and thickness h of the bonding ring can be configured. For instance, w3 can range from 100 μm to 150 μm, and h can be 150 nm. As shown in FIG. 10A, the bonding ring 32 can surround the cavity and be located at the edge of the first surface of the second substrate 31. The bonding ring can be a continuous annular structure, as shown in FIGS. 10A and 10B, or it can be a discontinuous ring or parallel strips, as long as the bonding ring ensures the necessary strength for the connection between the base and the cap layer. The shape of the bonding ring is not restricted by this disclosure.

In this embodiment, the bonding ring 32 can be fixed to the base through bonding, thereby fixing the base and the cap layer together. Due to the structural differences between the base and the multi-mode sensor body, the structures bonded to the bonding ring 32 also differ. The following provides an illustrative explanation of bonding methods one through five.

### Bonding Method One

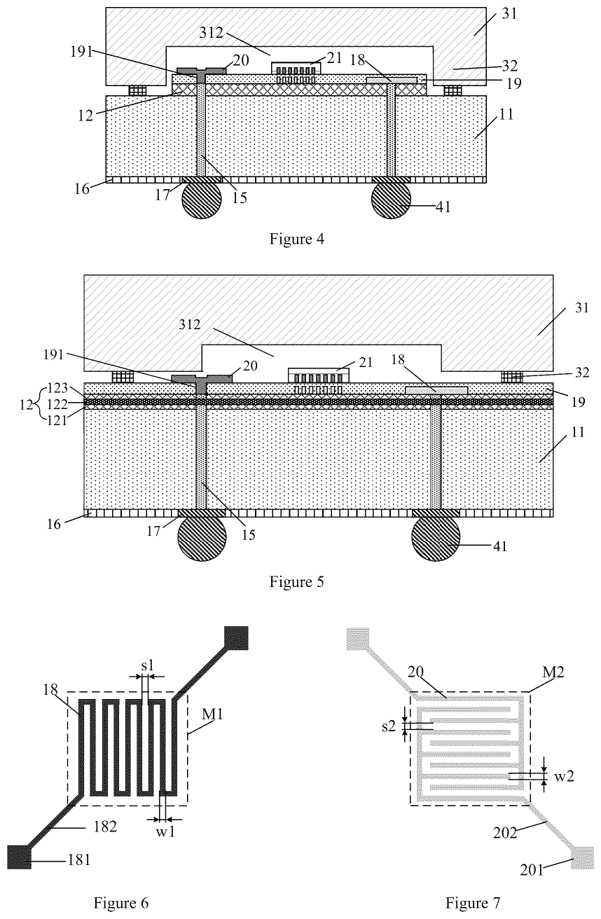

As shown in FIG. 4, if the multi-mode sensor body also comprises a second insulating layer, and the dielectric layer 12 covers the area of the first surface of the first substrate 11 corresponding to the cavity 312, and the second insulating layer 19 at most covers the exposed part of the dielectric layer 12, the bonding ring 32 is fixedly connected to the first surface of the first substrate 11 through bonding. This fixes the base and the cap layer together, with the multi-mode sensor body and the dielectric layer 12 located within the cavity 312.

### Bonding Method Two

As shown in FIG. 3, if the multi-mode sensor body also comprises a second insulating layer, and the dielectric layer 12 covers the entire area of the first surface of the first substrate 11, and the second insulating layer 19 at most covers the exposed part of the dielectric layer 12 corresponding to the cavity 312, the bonding ring 32 is fixedly connected to the dielectric layer 12 through bonding. This fixes the base and the cap layer together, with the multi-mode sensor body located within the cavity 312.

### Bonding Method Three

As shown in FIG. 5, if the multi-mode sensor body also comprises a second insulating layer, and the dielectric layer 12 covers the entire area of the first surface of the first substrate 11, and the second insulating layer covers the entire exposed part of the dielectric layer 12, the bonding ring 32 is fixedly connected to the second insulating layer 19 through bonding. This fixes the base and the cap layer together, with at least the sensing film layer 21 located within the cavity 312.

### Bonding Method Four

If the multi-mode sensor body only comprises the sensing electrodes and the sensing film layer, and the dielectric layer 12 covers the area of the first surface of the first substrate 11 corresponding to the cavity 312, the bonding ring 32 is fixedly connected to the first surface of the first substrate 11 through bonding. This fixes the base and the cap layer together, with the multi-mode sensor body and the dielectric layer 12 located within the cavity 312.

### Bonding Method Five

As shown in FIG. 1A, if the multi-mode sensor body only comprises the sensing electrodes and the sensing film layer, and the dielectric layer 12 covers the entire area of the first surface of the first substrate 11, the bonding ring 32 is fixedly connected to the dielectric layer 12 through bonding. This fixes the base and the cap layer together, with at least the sensing film layer 21 of the multi-mode sensor body located within the cavity 312.

In this embodiment, the position, size, and shape of the cavity 312 can be configured according to the position, size, and shape of the multi-mode sensor body, so that at least the sensing film layer 21 of the multi-mode sensor body is located within the cavity 312. The depth of the cavity 312 can range from 100 micrometers to 300 micrometers. For example, if the multi-mode sensor has the structure shown in FIG. 5, and the size of the sensing film layer 21 is between 100 μm×100 μm and 300 μm×300 μm, then the cavity 312 can have a cuboid structure with dimensions of 500 μm×500 μm×100 μm (with 100 μm as the depth).

In some embodiments, if the multi-mode sensor is a gas sensor or other sensors that need to interact with the external environment, the cavity 312 is arranged above the multi-mode sensor body, and both the cavity 312 and the material exchange via 311 are positioned above the sensing film layer 21. This ensures that the sensing film layer 21 can interact with the external environment and detect the target object. For substances corresponding to the detected object in the external environment (e.g., liquid phase, gas phase, solid dispersion phase), they can diffuse through the material exchange via 311 and come into full contact with the sensing film layer 21. The position, size, and shape of the cavity 312 can be configured according to the position, size, and shape of the multi-mode sensor body, so that at least the sensing film layer 21 of the multi-mode sensor body is located within the cavity 312 and aligned with the material exchange via 311. The depth of the cavity 312 can range from 100 micrometers to 300 micrometers.

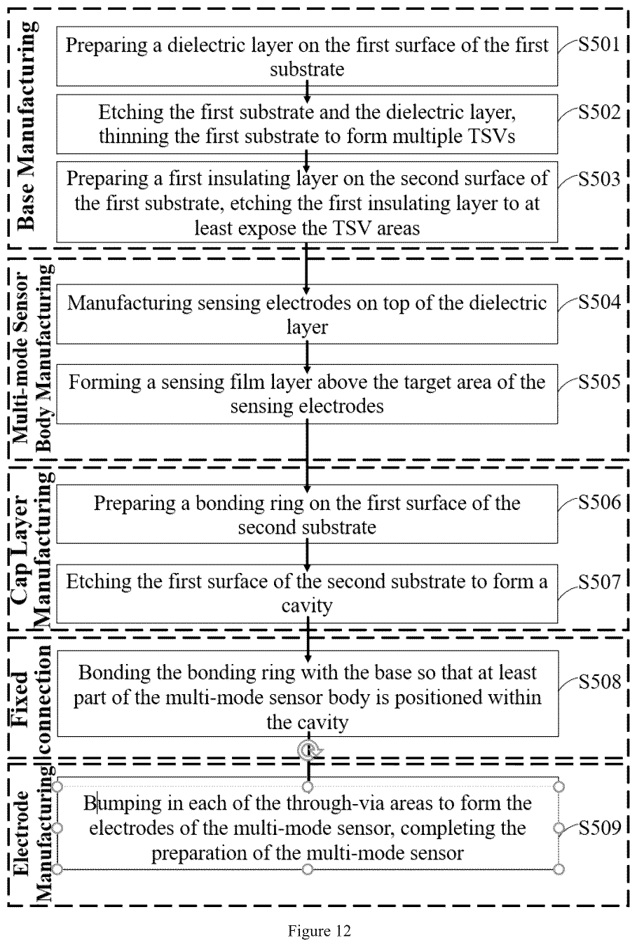

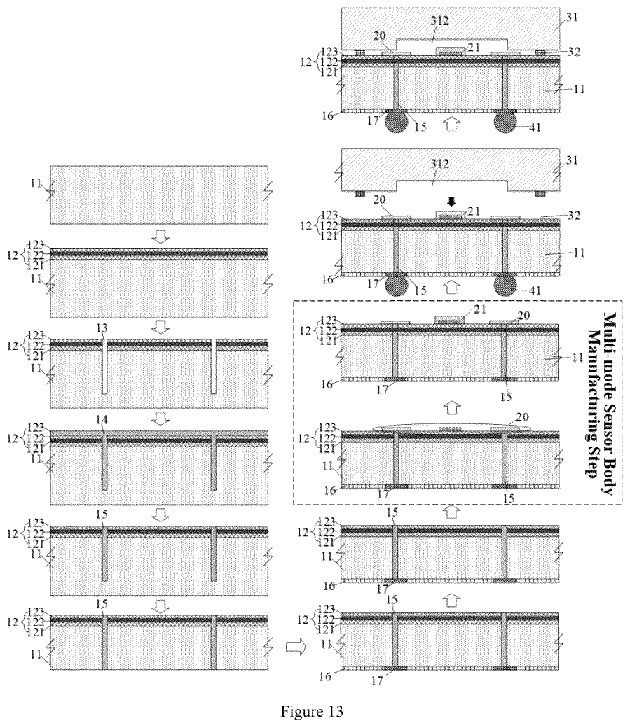

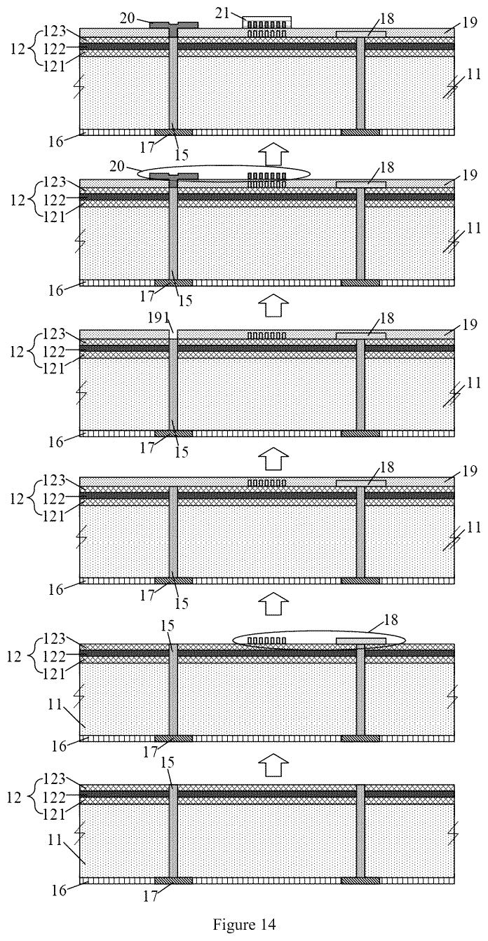

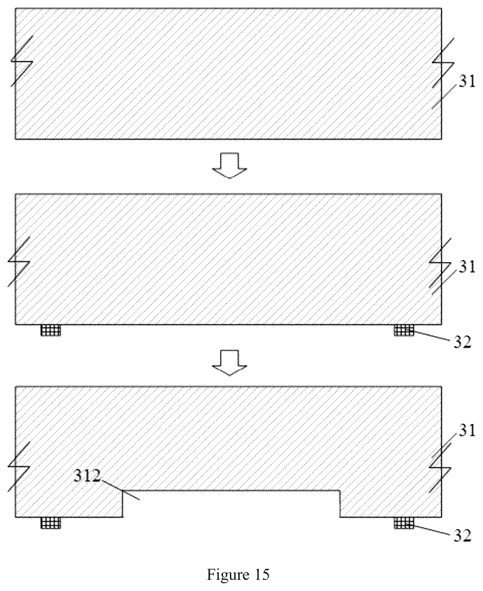

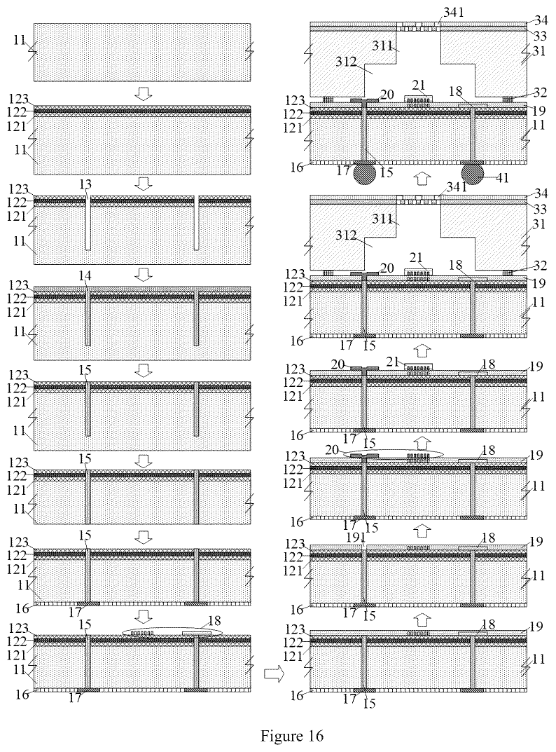

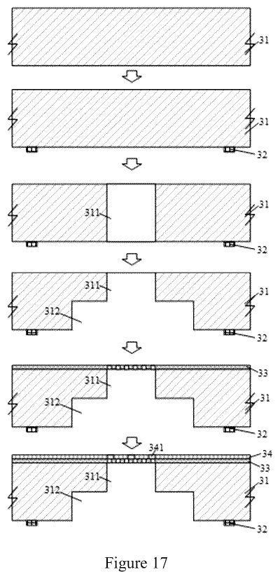

FIG. 12 shows a flowchart of the manufacturing method for a multi-mode sensor based on wafer-level packaging according to one embodiment of the present disclosure. FIG. 13 shows a schematic diagram of the manufacturing process of a multi-mode sensor based on wafer-level packaging according to one embodiment of the present disclosure. FIG. 14 shows a schematic diagram of the manufacturing process of the multi-mode sensor body in the manufacturing method for a multi-mode sensor based on wafer-level packaging according to one embodiment of the present disclosure. FIG. 15 shows a schematic diagram of the manufacturing process of the cap layer in the manufacturing method for a multi-mode sensor based on wafer-level packaging according to one embodiment of the present disclosure. FIG. 16 shows a schematic diagram of the manufacturing process of a gas sensor in the manufacturing method for a multi-mode sensor based on wafer-level packaging according to one embodiment of the present disclosure. FIG. 17 shows a schematic diagram of the manufacturing process of the cap layer for a gas sensor in the manufacturing method for a multi-mode sensor based on wafer-level packaging according to one embodiment of the present disclosure.

As shown in FIGS. 12-15, the method comprises the following steps: base manufacturing step, multi-mode sensor body manufacturing step, cap layer manufacturing step, fixed connection step, and electrode manufacturing step. Among these, the base manufacturing step comprises steps S501 to S503. The multi-mode sensor body manufacturing step comprises steps S504 to S505. The cap layer manufacturing step comprises steps S506 to S507. The fixed connection step comprises step S508. The electrode manufacturing step comprises step S509. In FIGS. 13 and 14, the manufacturing of the multi-mode sensor shown in FIG. 1 (assuming the dielectric layer is an ONO dielectric layer in FIG. 1) is taken as an illustrative example, showing the manufacturing process. In FIGS. 16 and 17, the manufacturing of the multi-mode sensor shown in FIG. 11 (assuming the dielectric layer is an ONO dielectric layer in FIG. 11) is taken as an illustrative example, showing the manufacturing process. It is understood that the base manufacturing step can be executed before, after, or simultaneously with the cap layer manufacturing step. The multi-mode sensor body manufacturing step is executed after the base manufacturing step, the fixed connection step is executed after the base manufacturing step, multi-mode sensor body manufacturing step, and cap layer manufacturing step, and the electrode manufacturing step is executed after the fixed connection step.

Base Manufacturing Step: This comprises steps S501 to S503.

In step S501, a dielectric layer 12 is prepared on the first surface of the first substrate 11. The dielectric layer 12 can be composed of a silicon dioxide layer 121, a silicon nitride layer 122, and another silicon dioxide layer 123. The dielectric layer 12 can be manufactured using the PECVD process.

In step S502, the first substrate 11 and the dielectric layer 12 are etched, and the first substrate 11 is thinned to form multiple TSVs 15.

In this step, as shown in FIG. 13, step S502 may comprise: Etching the first substrate 11 and the dielectric layer 12 to form multiple blind vias 13 necessary for the preparation of the multi-mode sensor; forming a silicon dioxide insulating layer on the surface of the blind vias 13 through thermal oxidation (which can prevent damage to the insulating layer during subsequent high-temperature processes). Then, an atomic layer deposition (ALD) process or a physical vapor deposition (PVD) process is used to successively prepare a TiN barrier layer and a Cu seed layer on the insulating layer's surface. A plating process can be used to fill the blind vias 13 with metal to form the metal structure 14 shown in FIG. 10B, followed by annealing to partially relieve the stress caused by the filled metal. Since metal structure 14 is also plated on the dielectric layer 12, chemical mechanical polishing (CMP) or similar processes can be continued to polish the metal structure 14 on the dielectric layer 12. After polishing, the second surface of the first substrate 11 is thinned until the blind vias 13 are exposed, resulting in the TSVs 15.

For clarity, the insulating layer, TiN barrier layer, and Cu seed layer within the TSVs are not shown in FIG. 10B. The insulating layer is used to achieve electrical insulation between the metal pillars in the TSVs 15 and the first substrate 11. The barrier layer is used to prevent the diffusion of electrode metals from the metal pillars in the TSVs 15 into the insulating layer and the first substrate 11.

In this process, dry etching methods such as inductively coupled plasma (ICP) can be used to etch the dielectric layer 12, while the Bosch process can be applied to etch the first substrate 11, ultimately forming multiple blind vias 13.

In step S503, a first insulating layer 16 is prepared on the second surface of the first substrate 11, and the first insulating layer 16 is etched to at least expose the through-via areas corresponding to each TSV 15, completing the manufacture of the base.

The first insulating layer 16 can be prepared using PECVD to prevent the diffusion of metals in the TSVs at high temperatures. Then, a photolithography process can be used to pattern the through-via areas, followed by using the ICP process to etch the first insulating layer 16 until the through-via areas are exposed. Subsequently, metal electrode deposition layer 17 can be deposited in the through-via areas through methods such as magnetron sputtering or evaporation, serving as the contact area for subsequent bumping (the manufacturing steps for the contact area are optional). Polishing during the TSV fabrication process and thinning in step S503 can eliminate wafer warpage caused by film stress, ensuring the smooth implementation of subsequent processes.

Multi-Mode Sensor Body Manufacturing Step: This comprises steps S504 to S505.

In step S504, the sensing electrodes 20 are prepared on the surface of the dielectric layer 12.

In this step, a photoresist can be coated on the surface of the dielectric layer 12. The photoresist is then patterned based on the structure and dimensions of the sensing electrodes 20 to expose the areas on the surface of the dielectric layer 12 where the sensing electrodes 20 need to be fabricated. Metal is then deposited using methods such as magnetron sputtering or evaporation to form the sensing electrodes 20, after which the excess photoresist on the surface of the dielectric layer 12 is removed.

In step S505, the sensing film layer 21 is manufactured above the target area of the sensing electrodes 20, completing the fabrication of the multi-mode sensor body.

In this step, a photolithography process is used to pattern the area above the target area of the sensing electrodes 20, exposing the regions on the surface of the sensing electrodes 20 where the sensing film layer 21 needs to be fabricated. The sensing material is then coated, and after stripping away the photoresist, the sensing film layer 21 is obtained, resulting in the multi-mode sensor body.

In one possible implementation, as shown in FIG. 14, if the multi-mode sensor body also comprises regulating electrodes and a second insulating layer, the manufacturing steps for the multi-mode sensor body may comprise preparing the regulating electrodes 18 on the surface of the dielectric layer 12. The second insulating layer 19 is then fabricated on the surface of the regulating electrodes 18 and the exposed dielectric layer 12; the second insulating layer 19 is etched to form electrode vias 191, exposing multiple TSVs 15 for connection to the sensing electrodes 20; sensing electrodes 20 are manufactured in the target area overlapping the regulating electrodes 18, and the sensing electrodes 20 are connected to the corresponding TSVs 15 through the electrode vias 191; finally, the sensing film layer 21 is fabricated above the target area, completing the manufacturing of the multi-mode sensor body.

In this implementation, photoresist can be coated on the surface of the dielectric layer 12, and based on the structure and dimensions of the regulating electrodes 18, the photoresist layer is patterned to expose the areas on the surface of the dielectric layer 12 where the regulating electrodes 18 need to be fabricated. Metal is deposited to form the regulating electrodes through methods such as magnetron sputtering or evaporation, and the excess photoresist on the surface of the dielectric layer 12 is removed. The second insulating layer can be deposited using the PECVD process. A photoresist can be coated on the surface of the second insulating layer 19, and based on the positions and dimensions of the TSVs 15 that connect to the sensing electrodes 20, the photoresist is patterned to expose the areas that need to be etched in the second insulating layer 19, which is then etched using a wet etching process to expose the TSVs 15 that connect to the sensing electrodes 20, followed by the removal of excess photoresist on the surface of the second insulating layer 19. A photoresist can also be coated on the surface of the second insulating layer 19, and based on the structure and dimensions of the sensing electrodes 20, the photoresist is patterned to expose the areas on the second insulating layer 19 where the sensing electrodes 20 need to be fabricated. Metal is deposited to form the sensing electrodes 20 using methods such as magnetron sputtering or evaporation, and the excess photoresist on the surface of the second insulating layer 19 is removed. The area above the target region of the sensing electrodes 20 is patterned using photolithography to expose the areas on the surfaces of the second insulating layer 19 and the sensing electrodes 20 that need to be prepared for the sensing film layer 21. The sensing material is then coated, and after stripping the photoresist, the sensing film layer 21 is obtained, resulting in the multi-mode sensor body.

In some embodiments, if the multi-mode sensor body also comprises a sensing structure, taking the case where the sensing structure is located above the base as an example, the pre-fabricated sensing structure can be installed at the corresponding position above the base. The sensing structure can also be directly fabricated above the base according to its 3D shape. For example, a photoresist can be coated above the base and exposed to define the area where the sensing structure will be placed, followed by fabricating the structural layer in that area. The structural layer can then be processed through etching or other fabrication processes to form the sensing structure. The preparation sequence of the sensing structure, the sensing film layer, and the sensing electrodes can be configured based on the position of the sensing structure and the vertical relationship between the sensing film layer and the sensing electrodes, with no limitation imposed by this disclosure.

FIGS. 13 to 17 illustrate the process for manufacturing a multi-mode sensor, but in practice, multiple multi-mode sensors can be synchronously fabricated on a single wafer. In one possible implementation, during the manufacturing of multiple multi-mode sensors on the wafer, different sensing materials can be coated on the surfaces of adjacent sensing electrodes to achieve the preparation of multi-mode sensors with different sensing functionalities. In this case, depending on the different sensing materials to be coated, the required sensing electrodes can be exposed using photolithography when applying a particular sensing material, while the remaining areas of the sensing electrodes that do not require this material can be covered with photoresist, and the photoresist can be removed after coating.

Cap Layer Manufacturing Step: This comprises steps S506 to S507.

In step S506, the bonding ring 32 is prepared on the first surface of the second substrate 31.

In this step, the bonding ring area can be patterned using photolithography, and then metal can be deposited using methods such as magnetron sputtering or evaporation, followed by removing the excess photoresist to obtain the bonding ring 32.

In step S507, the first surface of the second substrate 31 is etched to form the cavity 312.

In this case, the area of the first surface of the second substrate 31 corresponding to the cavity can be patterned using photolithography, and the patterned area of the second substrate 31 can be etched using the Bosch process to form the cavity 312.

In one possible implementation, if the multi-mode sensor is a gas multi-mode sensor, the cap layer manufacturing steps may comprise: etching the second substrate 31 to form a material exchange via 311 that penetrates through the second substrate 31 and corresponds to the target area. The Bosch process can be used to etch the second substrate 31 to create the material exchange via 311. The first surface of the second substrate 31 is etched to form a cavity 312 that connects to the material exchange via 311. This can be done by patterning the area of the first surface of the second substrate 31 corresponding to the cavity using photolithography and then etching the patterned area of the second substrate 31 using the Bosch process to create the cavity 312.

A pre-fabricated breathable membrane is then bonded to the second surface of the second substrate 31, at least covering the material exchange via 311, forming the breathable membrane layer 33. A dustproof mesh layer is fabricated above the breathable membrane layer 33, forming a layer that at least partially covers the breathable membrane layer 33 and has multiple through-vias 341. The dustproof mesh layer can be patterned using photolithography to expose the areas above the breathable membrane layer 33 and the second surface of the second substrate that need the dustproof mesh layer. Metal is deposited using methods such as magnetron sputtering or evaporation to form the dustproof mesh layer, and excess photoresist is removed, completing the preparation of the dustproof mesh layer 34.

In one possible implementation, if the multi-mode sensor is a gas multi-mode sensor and the cap layer comprises a dustproof mesh layer but does not comprise a breathable membrane layer, the cap layer manufacturing steps may comprise: etching the second substrate 31 to form a material exchange via 311 that penetrates through the second substrate 31 and corresponds to the target area. The first surface of the second substrate 31 is etched to form a cavity 312 that connects to the material exchange via 311. The dustproof mesh layer can be patterned using photolithography to expose the areas above the second surface of the second substrate where the dustproof mesh layer needs to be fabricated. Metal is deposited using methods such as magnetron sputtering or evaporation to form the dustproof mesh layer, and excess photoresist is removed, resulting in a dustproof mesh layer that at least partially covers the material exchange via 311 and comprises multiple through-vias.

Fixed Connection Step: This comprises step S508.

In step S508, the bonding ring 32 is fixedly connected to the base through bonding, ensuring that at least part of the multi-mode sensor body is located within the cavity 312.

During the bonding process, reverse compressive stress may be applied to the base to further alleviate warping.

Depending on the differences between the base and the structure of the multi-mode sensor body, step S508 may comprise any of the following implementations:

If the multi-mode sensor body does not comprise regulating electrodes and a second insulating layer, and the dielectric layer 12 covers the area of the first surface of the first substrate 11 corresponding to the cavity 312, the bonding ring 32 is fixedly connected to the first surface of the first substrate 11 through bonding. This ensures that the base and the cap layer are fixed together, with the multi-mode sensor body and the dielectric layer 12 located within the cavity 312.

If the multi-mode sensor body does not comprise regulating electrodes and a second insulating layer, and the dielectric layer 12 covers the entire area of the first surface of the first substrate 11, the bonding ring 32 is fixedly connected to the dielectric layer 12 through bonding. This ensures that the base and the cap layer are fixed together, with at least the sensing film layer 21 of the multi-mode sensor body located within the cavity 312. In this case, the multi-mode sensor ultimately achieves the connection state of the base and the cap layer shown in FIG. 1A.

If the multi-mode sensor body comprises regulating electrodes 18 and a second insulating layer 19, and the dielectric layer 12 covers the area of the first surface of the first substrate 11 corresponding to the cavity 312, and the second insulating layer 19 at most covers the exposed part of the dielectric layer 12, the bonding ring 32 is fixedly connected to the first surface of the first substrate 11 through bonding. This ensures that the base and the cap layer are fixed together, with the multi-mode sensor body and the dielectric layer 12 located within the cavity 312. In this case, the multi-mode sensor ultimately achieves the connection state of the base and the cap layer shown in FIG. 4.

If the multi-mode sensor body comprises regulating electrodes 18 and a second insulating layer 19, and the dielectric layer 12 covers the entire area of the first surface of the first substrate 11, and the second insulating layer 19 at most covers the exposed part of the dielectric layer 12 corresponding to the cavity 312, the bonding ring 32 is fixedly connected to the dielectric layer 12 through bonding. This ensures that the base and the cap layer are fixed together, with the multi-mode sensor body located within the cavity 312. In this case, the multi-mode sensor ultimately achieves the connection state of the base and the cap layer shown in FIG. 3.

If the multi-mode sensor body comprises regulating electrodes 18 and a second insulating layer 19, and the dielectric layer 12 covers the entire area of the first surface of the first substrate 11, and the second insulating layer 19 also covers the entire exposed area of the dielectric layer 12, then the bonding ring 32 is fixedly connected to the second insulating layer 19 through bonding. This ensures that the base and the cap layer are fixed together, with at least the sensing film layer 21 located within the cavity 312. In this case, the multi-mode sensor ultimately achieves the connection state of the base and the cap layer shown in FIG. 5.

Electrode Manufacturing Step: This comprises step S509.

In step S509, bumping is performed in each of the through-via regions to form the electrodes 41 of the multi-mode sensor, completing the fabrication of the multi-mode sensor. In this step, bumping can be performed using a laser bumping method.

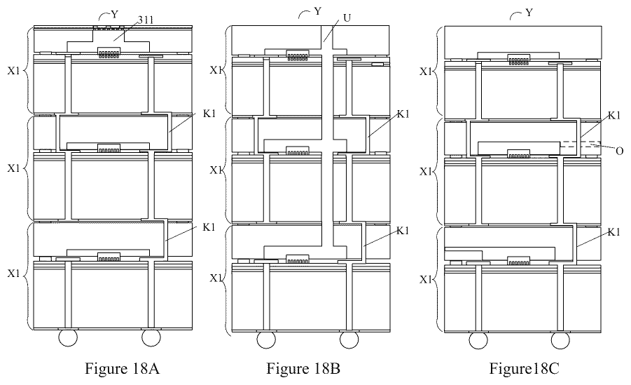

FIGS. 18A-18C illustrate the structural schematic of a multi-mode sensor module based on wafer-level packaging according to one embodiment of the present disclosure. As shown in FIGS. 18A-18C, by bonding the bottom surface of one multi-mode sensor X1 with the top surface of another multi-mode sensor X1, multiple multi-mode sensors X1 are connected, achieving the preparation of the multi-mode sensor module Y structure. It is noted that FIGS. 18A-18C schematically show that the multi-mode sensor module Y comprises three multi-mode sensors X1. The participating multi-mode sensors X1 can be of any functional type. In the multi-mode sensor module Y, the non-bottom-layer multi-mode sensors X1 can connect to the corresponding electrodes of the bottom multi-mode sensors X1 through the conductive pillars K1 in the cap layers of the underlying multi-mode sensors X1 and interlayer wiring (not shown in the figures).

In another possible design and connection method, if a multi-mode sensor X1 that needs to exchange materials with the external environment (such as chemicals, biological materials, physical changes, etc.) is connected to an intermediate or bottom layer, the connection can be realized through a silicon cap with material exchange vias on the sidewalls or the top. For example, as shown in FIG. 18A, for the multi-mode sensor on the top of the multi-mode sensor module Y that needs to contact external substances to be measured, the material exchange via 311 in the cap layer of this multi-mode sensor enables contact between the top multi-mode sensor and the external substance to be measured. Alternatively, as shown in FIG. 18B, through-vias U can be set to penetrate each multi-mode sensor X1 in the multi-mode sensor module Y, ensuring that the material exchange vias of each multi-mode sensor make contact with the external substances to be measured through the silicon cap. Additionally, as shown in FIG. 18C, for a specific multi-mode sensor in the multi-mode sensor module that needs to contact external substances to be measured, a via O can be set in the cap layer of the multi-mode sensor to achieve contact with the external substance to be measured.

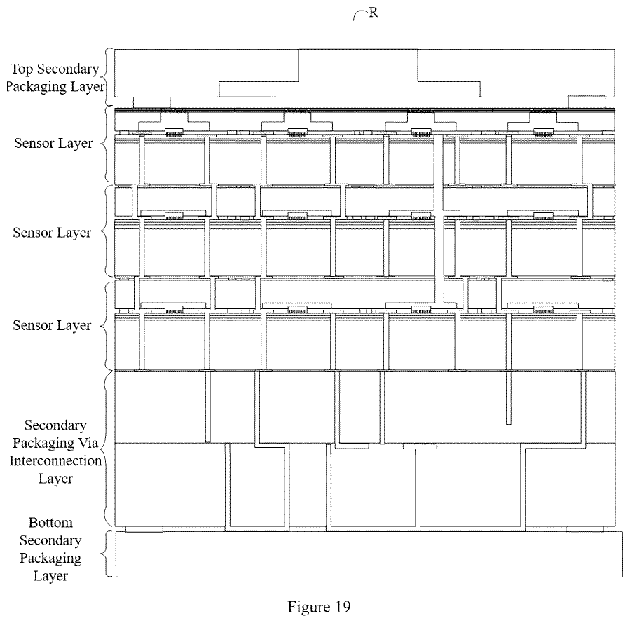

FIG. 19 shows a schematic diagram of the secondary packaging structure of a multi-mode sensor component based on wafer-level packaging according to one embodiment of the present disclosure. As shown in FIG. 19, the multi-mode sensor component R comprises a top secondary packaging layer, multiple sensor layers (only three layers are shown schematically in FIG. 19), a secondary packaging via interconnect layer, and a bottom secondary packaging layer. The top secondary packaging layer protects the multi-mode sensor component after secondary packaging and is also equipped with structures such as dustproof meshes and vias to facilitate contact between the multi-mode sensors inside the component and the external substances to be measured. Each sensor layer comprises multiple aforementioned multi-mode sensors, and the cap layers of the multi-mode sensors within the same sensor layer can form an integrated structure as the cap structure of that sensor layer. The entire cap structure can be arranged with corresponding structures based on the functions required by different multi-mode sensors, which facilitates the preparation of each sensor layer. The detection functions of the multi-mode sensors arranged on the same sensor layer can be the same or different; this disclosure does not impose any limitations on this. The secondary packaging via interconnect layer comprises TSVs and interconnect lines, allowing for the interconnection of multiple lateral sensor layers in the multi-mode sensor component. The bottom secondary packaging layer protects the interconnect lines within the secondary packaging via interconnect layer. Each layer is connected through wafer bonding. Through secondary packaging, the multi-mode sensor component achieves lateral and vertical integration, and the via interconnect layer further converts horizontal wiring into vertical wiring, saving space and enhancing the integration of the multi-mode sensor component. In some embodiments, the multiple sensor layers in the multi-mode sensor component R can also correspond to the aforementioned multi-mode sensor module Y based on wafer-level packaging.

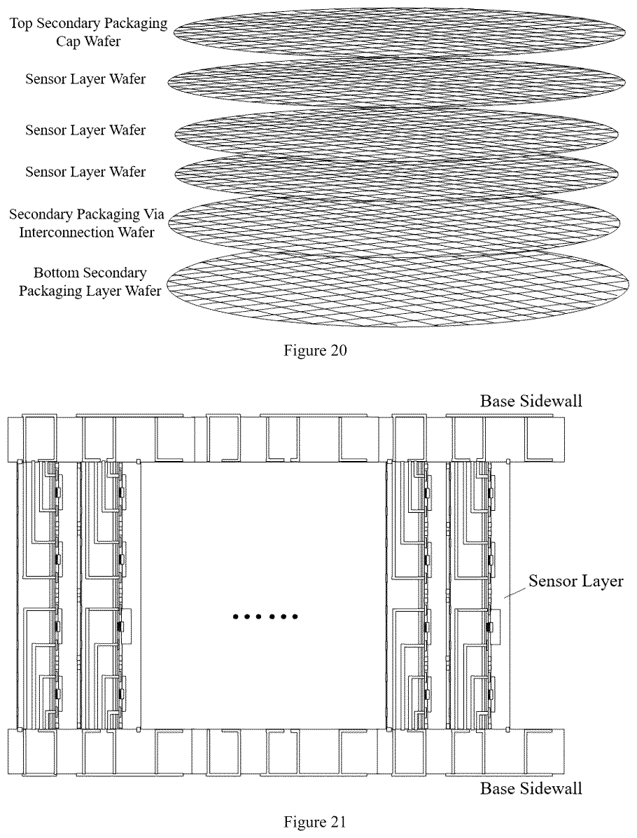

FIG. 20 illustrates the structural schematic of a multi-mode sensor array based on wafer-level packaging according to one embodiment of the present disclosure. As shown in FIG. 20, the multi-mode sensor array comprises a top secondary packaging cap wafer, multiple sensor layer wafers (for example, three sensor layer wafers are shown in the figure), a secondary packaging via interconnect wafer, and a bottom secondary packaging layer wafer. The top secondary packaging cap wafer protects the multi-mode sensor array and may comprise structures such as dustproof meshes and vias for exchanging with external substances to be measured.

In some embodiments, when the multi-mode sensor array is applied as a whole, each sensor layer wafer comprises multiple multi-mode sensors, and the cap layers of the multi-mode sensors in the same sensor layer wafer can form an integrated cap structure. Different functional multi-mode sensors are arranged on each sensor layer wafer, encapsulated within the same structure by the secondary packaging layer, forming the multi-mode sensor array. The secondary packaging via interconnect wafer comprises TSVs and interconnect lines, allowing for interconnection of multiple lateral sensors in the multi-mode sensor array. The bottom secondary packaging wafer protects the interconnect lines within the via interconnect wafer. All wafers are connected through wafer-level bonding. Testing and dicing can be performed after the wafer-level fabrication and packaging processes are completed, significantly improving testing efficiency and production efficiency. In some embodiments, the aforementioned multi-mode sensor component R can be a part of the multi-mode sensor array, meaning that the multi-mode sensor array comprises multiple multi-mode sensor components R arranged in an array. Compared to dicing a single multi-mode sensor or multi-mode sensor component and then performing bonding and packaging, the efficiency of the wafer-level packaging process and the uniformity of product quality are significantly higher.

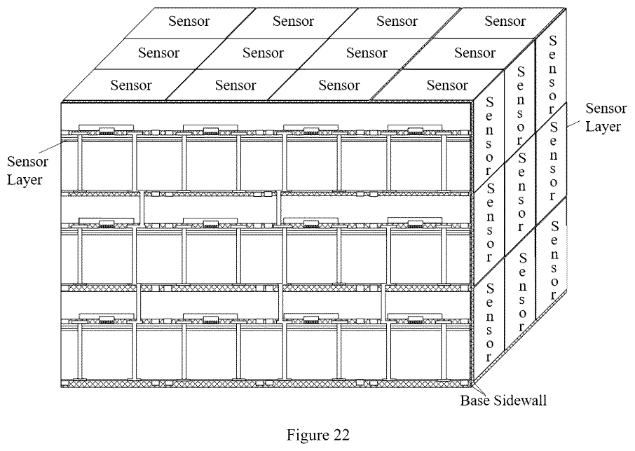

FIGS. 21 and 22 illustrate the multi-package structure of a multi-mode sensor component based on wafer-level packaging according to another embodiment of the present disclosure. As shown in FIGS. 21 and 22, the multi-mode sensor component comprises multiple sensor layers and at least two base sidewalls. In some embodiments, each sensor layer can be a sensor layer wafer, and each base sidewall can also be a wafer; this disclosure does not impose any limitations in this regard. Each sensor layer comprises multiple multi-mode sensors, and each multi-mode sensor is laterally connected to the corresponding base sidewalls through TSVs and interconnect lines in its base. The interconnections are bonded and connected to the surface of the base sidewalls. Each base sidewall can be bonded and interconnected with multiple sensor layers, and each sensor layer can also be bonded and interconnected with multiple base sidewall wafers. Ultimately, the multi-mode sensor component can be assembled onto a PCB using the base sidewalls, achieving a 3D structural arrangement of the multi-mode sensor component to meet subsequent assembly requirements under 3D mounting conditions.

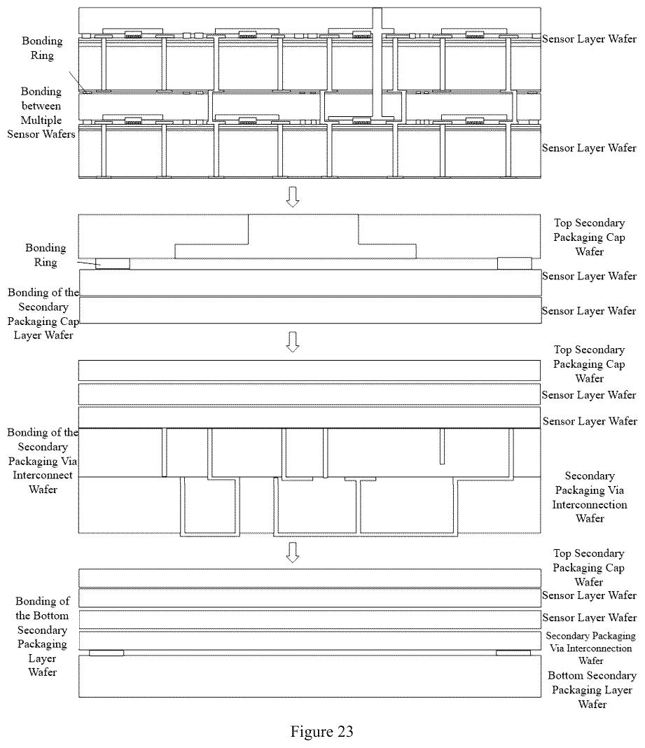

FIG. 23 illustrates the manufacturing process schematic of the secondary packaging of a multi-mode sensor array based on wafer-level packaging according to one embodiment of the present disclosure. As shown in FIG. 23, the method comprises the following steps: bonding between multiple sensor wafers, bonding of the secondary packaging cap layer wafer, preparation and bonding of the secondary packaging via interconnect wafer, bonding of the bottom secondary packaging layer wafer, and wafer dicing. The preparation process of multi-mode sensors on the sensor wafer is described above and will not be repeated here.

Bonding Between Multiple Sensor Wafers: As shown in FIG. 23, bonding rings are prepared in the outer peripheral areas corresponding to each multi-mode sensor at the top of the bottom sensor layer wafer. This can be accomplished by patterning the bonding ring area using photolithography, followed by metal deposition using methods such as magnetron sputtering or evaporation. Afterward, excess photoresist is removed to obtain the bonding rings. Similarly, bonding rings are prepared in the corresponding areas at the bottom of the previous sensor layer substrate wafer. Subsequently, the bonding rings on the adjacent two sensor layer wafers are connected through wafer bonding.

Bonding of the Secondary Packaging Cap Layer: As shown in FIG. 23, bonding rings are prepared in the required secondary packaging boundary regions at the outer periphery of the top sensor layer wafer. The size and position of these bonding rings should correspond to the size and position of the bonding rings on the secondary packaging cap wafer. This can be achieved by patterning the bonding ring area using photolithography, followed by metal deposition using methods such as magnetron sputtering or evaporation. Afterward, excess photoresist is removed to obtain the bonding rings. Finally, the top sensor layer wafer is connected to the bonding rings on the secondary packaging cap wafer through wafer bonding.

Preparation of the Secondary Packaging Via Interconnect Wafer (Not Shown in the Figure):

First, prepare the lower interconnect layer by implementing the same method as in step S502 to achieve silicon via preparation. Then, interconnect lines are fabricated on both the front and back sides of the substrate that has the vias, connecting multiple silicon via contacts to enable communication of sensing signals between different device groups. The line preparation can be achieved by first patterning photoresist using photolithography, followed by metal deposition in the recessed areas of the photoresist, and then removing the photoresist to form interconnect patterns. A bonding ring is prepared around the perimeter of the sensor group area on the surface of the upper interconnect layer corresponding to the sensor group. The same method is used to prepare a bonding ring around the perimeter of the sensor group area on the surface of the upper interconnect layer. The bonding rings on the bottom of the adjacent upper interconnect substrate are connected to the top of the lowest interconnect layer through wafer bonding, ensuring that the lines above the sensing lower interconnect layer connect to the lines at the bottom of the upper interconnect layer. The upper substrate then continues as the lowest interconnect substrate for the fixation and vertical interconnection of the next interconnect substrate until all interconnect layers are fully stacked.

Wafer Bonding of the Secondary Packaging Via Interconnect Wafer: As shown in FIG. 23, the bonding ring on the top of the secondary packaging via interconnect wafer is bonded to the bottom of the sensor layer wafer, connecting the two wafers together.

Bonding of the Bottom Secondary Packaging Wafer: As shown in FIG. 23, a bonding ring is prepared around the perimeter corresponding to the sensor area on the top surface of the bottom secondary packaging wafer. This is then wafer-bonded to the bottom of the secondary packaging via interconnect wafer to achieve the connection.

Wafer Dicing: The diced wafer after secondary packaging is cut in the peripheral area of the multi-mode sensor group to obtain individual multi-mode sensors, sensor components, etc. The cutting process can utilize laser cutting or mechanical dicing. This wafer-level bonding and cutting method can greatly improve testing efficiency and production efficiency. Compared to dicing a single sensor after cutting and then performing bonding and packaging, the efficiency and uniformity of product quality in this wafer-level packaging process show significant improvements.

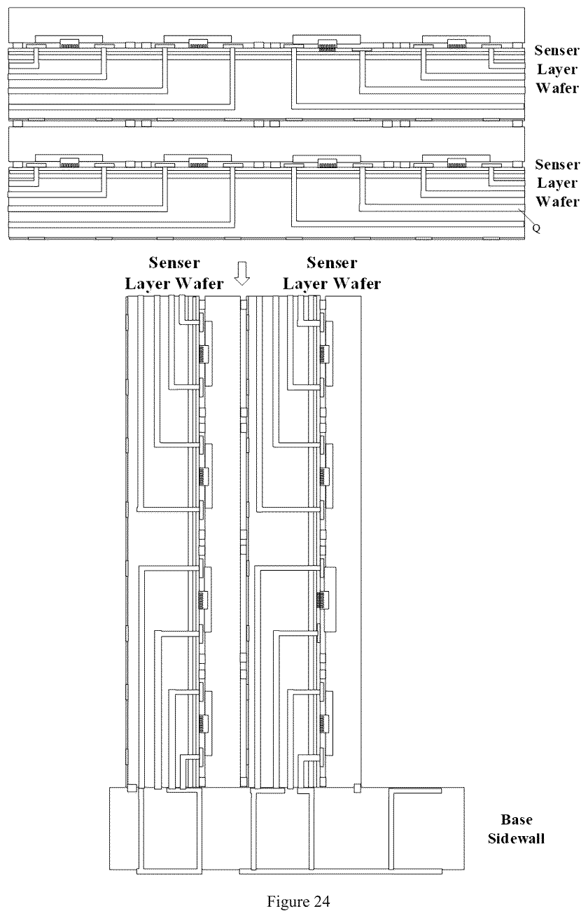

FIG. 24 illustrates the schematic of the manufacturing process for the multi-package structure of the multi-mode sensor component based on wafer-level packaging according to one embodiment of the present disclosure. This method is used to achieve the preparation of the multi-mode sensor component as shown in FIGS. 21 and 22, and comprises the following steps: preparation of lateral interconnect lines for multiple sensor wafers, preparation and bonding of the base sidewalls. For simplicity, only part of the sensor layer's base sidewalls is schematically shown in FIG. 24.

Preparation of Lateral Interconnect Lines for Multiple Sensor Wafers: As shown in FIG. 24, the side of the wafer after bonding multiple sensor layer wafers is polished, followed by photolithography to determine the positions for the required etching vias. The etching process then connects the vias with the device silicon vias. The etching process can be deep silicon etching. Different depths of vias can be processed with separate photolithography and etching. After the deep via Q is completed, a metal deposition process fills the via, laterally extending the electrodes. The metal deposition process can be PVD.

Preparation and Bonding of the Base Sidewalls: As shown in FIG. 24, after the base sidewalls are prepared, each sensor layer wafer is bonded to the sidewalls.

It can be understood that the multi-mode sensor components and multi-mode sensor arrays based on multi-mode sensors presented in this disclosure are merely illustrative examples of secondary packaging and multiple packaging. In practice, secondary, tertiary, and more levels of packaging can be performed based on multi-mode sensors to achieve the desired structures, and this disclosure imposes no restrictions on such variations.

This disclosure further demonstrates the low-stress wafer-level multi-mode sensor array preparation process, which employs stress dynamic control and compensation methods during the manufacturing of the multi-mode sensor wafer. Conventional processing techniques that typically lead to increased wafer warpage are optimized for low stress to achieve a lower degree of warpage in the final product wafer, thereby reducing the risk of wafer cracking during subsequent bonding, improving process compatibility, and enhancing yield.

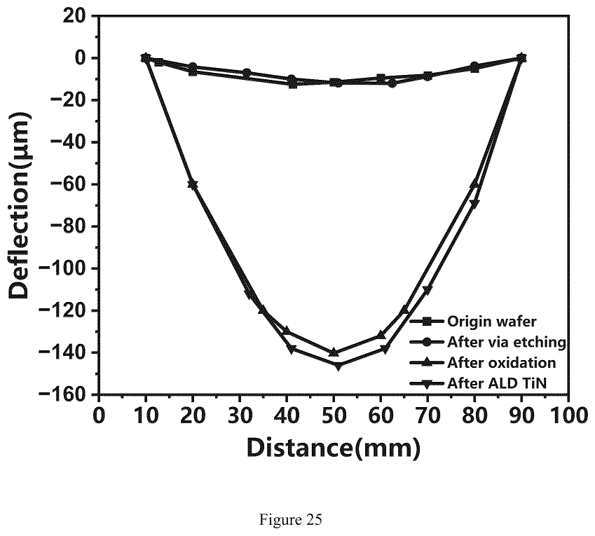

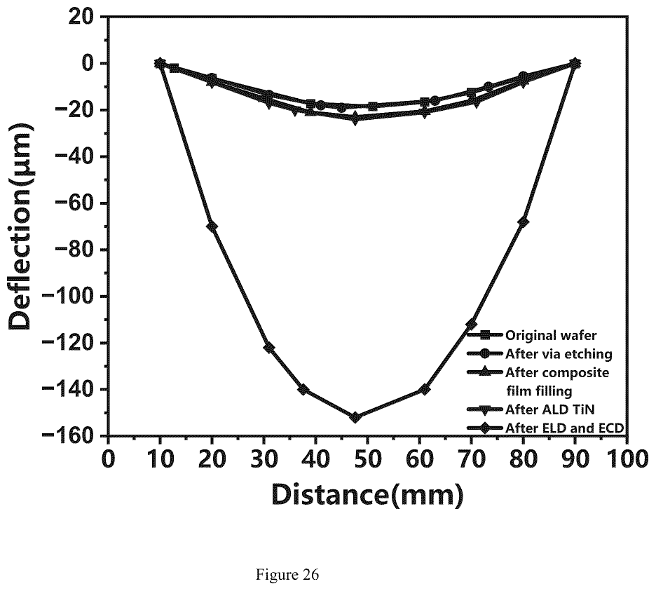

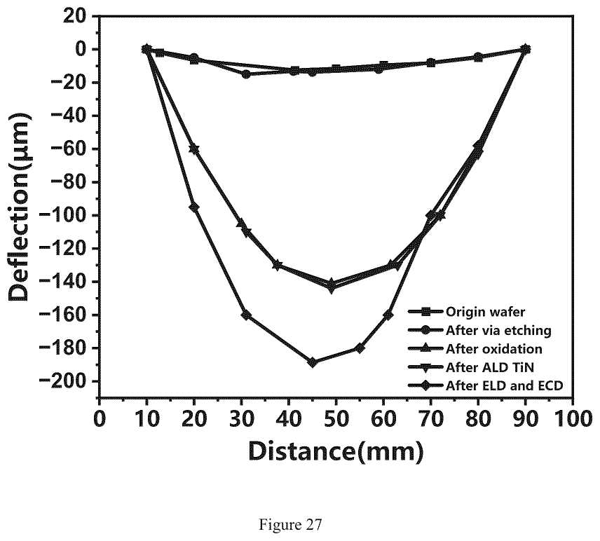

In the substrate preparation method in step S502, technical optimizations for low stress can be applied to the insulating layer deposition and metal electroplating processes, which are prone to causing significant stress in the wafer during the substrate preparation. For example, FIG. 25 shows the characterization curves of wafer surface warpage after each critical step (including etching, oxide layer preparation, and barrier layer TiN preparation) in the substrate preparation process using a silicon dioxide insulating layer and metal electroplating. After the electroplating fills the vias, the wafer surface warpage exceeds the detection range limit of the equipment. FIG. 26 illustrates the characterization curves of wafer surface warpage after using a silicon dioxide/silicon nitride composite film layer as the insulating layer. The thermal expansion coefficients of silicon dioxide and silicon nitride are opposite, so using a composite film layer of these two materials can reduce the overall thermal deformation of the composite film during high-temperature film formation processes, thereby decreasing the stress and warpage imposed on the wafer by this process. FIG. 27 shows the characterization curves of wafer surface warpage after filling vias using a low-stress slow electroplating process. The use of a slow electroplating process can improve the grain size of the metal film layer obtained by electroplating and the quality of the metal film, achieving more uniform metal filling while the gentler filling process can reduce the warpage of the wafer caused by the growth of the metal film layer, thus achieving low-stress technology optimization and multi-mode sensor manufacturing. Additionally, during the wafer-level packaging process stage, the bonding process applies compressive stress opposite to the warpage direction of the substrate wafer, further alleviating warpage in the packaged product.

It should be noted that although the above embodiments have been introduced as examples of the wafer-level packaged multi-mode sensors and their manufacturing methods, those skilled in the art will understand that this disclosure is not limited to these. In fact, users may flexibly set various structures and steps of the multi-mode sensor according to their personal preferences and/or actual application scenarios, as long as they conform to the technical solutions of this disclosure.

The various embodiments of the present disclosure have been described above. The description provided is exemplary and not exhaustive, and is not limited to the disclosed embodiments. Many modifications and changes will be apparent to those skilled in the art without departing from the scope and spirit of the described embodiments. The terminology used herein is chosen to best explain the principles of the various embodiments, practical applications, or improvements in technology in the market, or to enable other ordinary skilled personnel in the art to understand the disclosed embodiments.

What is claimed is:

1. A multi-mode sensor based on wafer-level packaging, wherein the multi-mode sensor comprises a base, a multi-mode sensor body, a cap layer, and multiple electrodes;
the base comprises: a first substrate, a dielectric layer, a first insulating layer, and multiple through silicon vias (TSVs), wherein the dielectric layer covers at least a portion of the first surface of the first substrate; the TSVs penetrate the first substrate and the dielectric layer; the first insulating layer covers the second surface of the first substrate and at least exposes the TSVs, with the first substrate being a silicon substrate;
the multiple electrodes are arranged within the TSV areas and electrically connected to the corresponding TSVs;
the multi-mode sensor body comprises sensing electrodes and a sensing film layer, wherein the sensing electrodes are located above the dielectric layer and connected to the corresponding TSVs; the sensing film layer covers the target area of the sensing electrodes; and
the cap layer comprises a second substrate and a bonding ring, wherein the first surface of the second substrate is provided with a cavity, and at least part of the multi-mode sensor body is located within the cavity; the bonding ring is arranged on the first surface of the second substrate and surrounds the cavity in a closed loop, used to fix the base and the cap layer together.

2. The multi-mode sensor according to claim 1, wherein the multi-mode sensor body further comprises: regulating electrodes and a second insulating layer;
the regulating electrodes are located above the dielectric layer and connected to the corresponding TSVs; and
the second insulating layer is located above the dielectric layer and at least covers the regulating electrodes, and the second insulating layer is provided with electrode vias that expose the TSVs connected to the sensing electrodes;
wherein the sensing electrodes are located above the second insulating layer, with the target area overlapping the regulating electrodes and connected to the corresponding TSVs through the electrode vias.

3. The multi-mode sensor according to claim 1, wherein the dielectric layer covers the area of the first surface of the first substrate corresponding to the cavity, and the bonding ring is fixedly connected to the first surface of the first substrate, so that the base and the cap layer are fixed together, and the multi-mode sensor body and the dielectric layer are located within the cavity; or
the dielectric layer covers the entire area of the first surface of the first substrate, and the bonding ring is fixedly connected to the dielectric layer, so that the base and the cap layer are fixed together, and at least the sensing film layer of the multi-mode sensor body is located within the cavity.

4. The multi-mode sensor according to claim 2, wherein the dielectric layer covers the area of the first surface of the first substrate corresponding to the cavity, and the second insulating layer covers at most the exposed part of the dielectric layer, and the bonding ring is fixedly connected to the first surface of the first substrate, so that the base and the cap layer are fixed together, and the multi-mode sensor body and the dielectric layer are located within the cavity; or
the dielectric layer covers the entire area of the first surface of the first substrate, and the second insulating layer covers at most the exposed part of the dielectric layer corresponding to the cavity, and the bonding ring is fixedly connected to the dielectric layer, so that the base and the cap layer are fixed together, and the multi-mode sensor body is located within the cavity; or
the dielectric layer covers the entire area of the first surface of the first substrate, and the second insulating layer covers the entire exposed part of the dielectric layer, and the bonding ring is fixedly connected to the second insulating layer, so that the base and the cap layer are fixed together, and at least the sensing film layer is located within the cavity.

5. The multi-mode sensor according to claim 2, wherein the shape of the regulating electrodes comprises an extendable shape, wherein the extendable shape is any one of a serpentine shape or an S-shape; and/or
the sensing electrodes comprise interdigitated electrodes and/or intersecting electrodes, and the target area is a periodic pattern area of the sensing electrodes, wherein the size of the extendable shape area of the regulating electrodes matches and overlaps the target area; and/or
the multi-mode sensor body further comprises a sensing structure located above or inside the base, the sensing structure comprising at least one of the following: multiple composite film layers or a geometric structure with a preset three-dimensional (3D) shape.

6. The multi-mode sensor according to claim 2, wherein the multi-mode sensor body detects external gases, and the second surface of the second substrate is further provided with a material exchange via that corresponds to and connects to the target area of the sensor.

7. The multi-mode sensor according to claim 6, wherein the cap layer further comprises:
a breathable membrane layer located above the second surface of the second substrate, covering at least the material exchange via.

8. The multi-mode sensor according to claim 7, wherein the cap layer further comprises:
a dustproof mesh layer, located above the second surface of the second substrate and covering at least the area of the breathable membrane corresponding to the material exchange via, with the dustproof mesh layer being provided with multiple through-vias corresponding to the material exchange via.

9. A manufacturing method for a multi-mode sensor based on wafer-level packaging, wherein it is used to manufacture a multi-mode sensors based on wafer-level packaging, wherein the multi-mode sensor comprises a base, a multi-mode sensor body, a cap layer, and multiple electrodes;
the base comprises: a first substrate, a dielectric layer, a first insulating layer, and multiple TSVs, wherein the dielectric layer covers at least a portion of the first surface of the first substrate; the TSVs penetrate the first substrate and the dielectric layer; the first insulating layer covers the second surface of the first substrate and at least exposes the TSVs, with the first substrate being a silicon substrate;
the multiple electrodes are arranged within the TSV areas and electrically connected to the corresponding TSVs;
the multi-mode sensor body comprises sensing electrodes and a sensing film layer, wherein the sensing electrodes are located above the dielectric layer and connected to the corresponding TSVs; the sensing film layer covers the target area of the sensing electrodes; and
the cap layer comprises a second substrate and a bonding ring, wherein the first surface of the second substrate is provided with a cavity, and at least part of the multi-mode sensor body is located within the cavity; the bonding ring is arranged on the first surface of the second substrate and surrounds the cavity in a closed loop, used to fix the base and the cap layer together,
the method comprising the following steps: base manufacturing step, multi-mode sensor body manufacturing step, cap layer manufacturing step, fixed connection step, and electrode manufacturing step.
base manufacturing step: preparing a dielectric layer on the first surface of the first substrate, etching the first substrate and the dielectric layer, thinning the first substrate to form multiple TSVs, preparing a first insulating layer on the second surface of the first substrate, and etching the first insulating layer to at least expose the through-via areas corresponding to the TSVs, thereby forming the base of the multi-mode sensor;
multi-mode sensor body manufacturing step: manufacturing sensing electrodes on top of the dielectric layer, and forming a sensing film layer above the target area of the sensing electrodes, thereby obtaining the multi-mode sensor body;
cap layer manufacturing step: preparing a bonding ring on the first surface of the second substrate, and etching the first surface of the second substrate to form a cavity, thereby forming the cap layer of the multi-mode sensor;
fixed connection step: bonding the bonding ring with the base so that at least part of the multi-mode sensor body is positioned within the cavity; and
electrode manufacturing step: bumping in each of the through-via areas to form the electrodes of the multi-mode sensor, and completing the preparation of the multi-mode sensor.

10. The method according to claim 9, wherein manufacturing the sensing electrodes above the dielectric layer, and forming the sensing film layer above the target area of the sensing electrodes, thereby obtaining the multi-mode sensor body, comprises:
sequentially manufacturing regulating electrodes and a second insulating layer above the dielectric layer, wherein the second insulating layer at least covers the regulating electrodes;
etching the second insulating layer to form electrode vias, exposing the TSVs connected to the sensing electrodes;
manufacturing the sensing electrodes on the second insulating layer, wherein the target area overlaps the regulating electrodes, and the sensing electrodes are connected to the corresponding TSVs through the electrode vias; and
manufacturing the sensing film layer above the target area, thereby forming the multi-mode sensor body.

11. The method according to claim 9, wherein the bonding ring is fixedly connected to the base by a bonding method, comprises at least one of the following steps:
if the dielectric layer covers the area of the first surface of the first substrate corresponding to the cavity, the bonding ring is fixedly connected to the first surface of the first substrate by a bonding method, thereby fixing the base and the cap layer together, with the multi-mode sensor body and the dielectric layer located within the cavity; or
if the dielectric layer covers the entire area of the first surface of the first substrate, the bonding ring is fixedly connected to the dielectric layer by a bonding method, thereby fixing the base and the cap layer together, with at least the sensing film layer of the multi-mode sensor body located within the cavity.

12. The method according to claim 10, wherein the bonding ring is fixedly connected to the base by a bonding method, comprises at least one of the following steps:
if the dielectric layer covers the area of the first surface of the first substrate corresponding to the cavity and the second insulating layer covers at most the exposed part of the dielectric layer, then the bonding ring is fixedly connected to the first surface of the first substrate by a bonding method, thereby fixing the base and the cap layer together, with the multi-mode sensor body and the dielectric layer located within the cavity; or
if the dielectric layer covers the entire area of the first surface of the first substrate, and the second insulating layer covers at most the exposed part of the dielectric layer corresponding to the cavity, then the bonding ring is fixedly connected to the dielectric layer by a bonding method, thereby fixing the base and the cap layer together, with the multi-mode sensor body located within the cavity; or
if the dielectric layer covers the entire area of the first surface of the first substrate and the second insulating layer also covers the entire exposed part of the dielectric layer, then the bonding ring is fixedly connected to the second insulating layer by a bonding method, thereby fixing the base and the cap layer together, with at least the sensing film layer located within the cavity.

13. The method according to claim 10, wherein the shape of the regulating electrodes comprises an extendable shape, the extendable shape is any one of a serpentine shape or an S-shape;
the sensing electrodes comprise interdigitated electrodes and/or intersecting electrodes, with the target area being a periodic pattern area of the sensing electrodes, wherein the size of the extendable shape area of the regulating electrodes matches and overlaps the target area; and/or
the multi-mode sensor body further comprises a sensing structure, wherein the sensing structure is located above or inside the base, and the sensing structure comprises at least one of the following: multiple composite film layers or a geometric structure with a preset 3D shape.

14. The method according to claim 10, wherein the cap layer manufacturing step further comprises:
etching the second substrate before forming the cavity on the first surface of the second substrate, and creating a material exchange via that penetrates through the second substrate and corresponds to the target area, wherein the cavity is connected to the material exchange via.

15. The method according to claim 14, wherein the cap layer manufacturing step further comprises:
adhering a pre-prepared breathable membrane to the second surface of the second substrate, and covering at least the material exchange via, thereby forming a breathable membrane layer.

16. The method according to claim 15, wherein the cap layer manufacturing step further comprises:
preparing a dustproof mesh layer above the breathable membrane layer, and forming a portion that covers at least the breathable membrane layer and is provided with multiple through-vias.

17. A multi-mode sensor module based on wafer-level packaging, comprising:
multiple multi-mode sensors stacked vertically in succession, wherein the multi-mode sensors are a multi-mode sensors based on wafer-level packaging, and the multi-mode sensor comprises a base, a multi-mode sensor body, a cap layer, and multiple electrodes;
the base comprises: a first substrate, a dielectric layer, a first insulating layer, and multiple TSVs, wherein the dielectric layer covers at least a portion of the first surface of the first substrate; the TSVs penetrate the first substrate and the dielectric layer; the first insulating layer covers the second surface of the first substrate and at least exposes the TSVs, with the first substrate being a silicon substrate;
the multiple electrodes are arranged within the TSV areas and electrically connected to the corresponding TSVs;
the multi-mode sensor body comprises sensing electrodes and a sensing film layer, wherein the sensing electrodes are located above the dielectric layer and connected to the corresponding TSVs; the sensing film layer covers the target area of the sensing electrodes; and
the cap layer comprises a second substrate and a bonding ring, wherein the first surface of the second substrate is provided with a cavity, and at least part of the multi-mode sensor body is located within the cavity; the bonding ring is arranged on the first surface of the second substrate and surrounds the cavity in a closed loop, used to fix the base and the cap layer together.
